(19) United States
(12) Patent Application Publication
(10) Pub. No.: US 2012/0032932 A1
(43) Pub. Date: Feb. 9, 2012

(54) SIGNAL DRIVER AND DISPLAY DEVICE

(75) Inventor: Tomokazu KOJIMA, Osaka (JP)

(73) Assignee: Panasonic Corporation, Osaka (JP)

(21) Appl. No.: 13/278,596

(22) Filed: Oct. 21, 2011

Related U.S. Application Data
(63) Continuation of application No. PCT/JP2010/006486, filed on Nov. 4, 2010.

(30) Foreign Application Priority Data
Feb. 1, 2010 (JP) 2010-020669

(51) Int. Cl. G09G 5/00; H03F 3/45

(52) U.S. Cl. 345/204; 330/253

(57) ABSTRACT

Provided is a signal driver including: operational amplifier circuits; a voltage generating unit configured to generate voltage signals; and selecting units configured to select one of the voltage signals, and to output the selected voltage signal as a correction voltage signal to a corresponding one of the operational amplifier circuits, each of the operational amplifier circuits including a differential amplifier and a correction current supply unit, and the differential amplifier including: first and second differential transistors forming a differential pair; and a current source transistor that supplies a current to source terminals of the first and the second differential transistors, wherein the correction current supply unit is configured to supply a drain terminal of the first differential transistor with a correction current corresponding to the correction voltage signal to adjust an input offset voltage of the operational amplifier circuit.

### CROSS REFERENCE TO RELATED APPLICATION

This is a continuation application of PCT application No. PCT/JP2010/006486 filed on Nov. 4, 2010, designating the United States of America.

### BACKGROUND OF THE INVENTION

(1) Field of the Invention

The present invention relates to an operational amplifier circuit, a signal driver, a display device, and an offset voltage adjusting method, and in particular, to an operational amplifier circuit that can adjust an input offset voltage.

(2) Description of the Related Art

In recent years, liquid crystal panels and organic electroluminescence (EL) panels have been used in portable equipment, compact mobile equipment, and large panels. Furthermore, the liquid crystal panels and organic EL panels have also been used in display devices for video equipment, such as TVs, where the market is increasingly expanding. The quality of display panels has been increasing in order to obtain more natural images in such display devices. In addition, display driver LSIs included in the display devices need reduction in variation of output voltages between output terminals.

For example, Japanese Unexamined Patent Application Publication No. 2007-116493 (hereinafter referred to as Patent Reference 1) discloses a conventional technique for adjusting an input offset voltage of an operational amplifier circuit, as a method of reducing the variation of output voltages.

An output circuit 300 that is the operational amplifier circuit described in Patent Reference 1 will be described hereinafter.

FIG. 47 illustrates a structure of the output circuit 300 described in Patent Reference 1.

In the output circuit 300 in FIG. 47, pairs of resistors and switches are connected in parallel to source terminals of differential transistors in a differential stage and drain terminals of current source transistors in the differential stage.

The output circuit 300 in FIG. 47 includes an operational amplifier circuit including differential transistors 302 and 304, a resistor RA1 connected between the differential transistor 302 and a connecting point 306, and a resistor RB1 connected between the differential transistor 304 and the connecting point 306.

Furthermore, the output circuit 300 further includes pairs of resistors RA2, RA3, RA4, . . . and switches 310 connected between the differential transistor 302 and the connecting point 306, and similarly, pairs of resistors RB2, RB3, RB4, . . . and switches 310 connected between the differential transistor 304 and the connecting point 306.

The operations of the output circuit 300 having such a structure will be described.

First, the output circuit 300 outputs a signal in a state where the switches 310 connected to the resistors RA2, RA3, RA4, . . . are turned on and the switches 310 connected to the resistors RB2, RB3, RB4, . . . are turned off. Since the resistors RA2, RA3, RA4, . . . are connected in parallel, when the same amount of current flows through the differential transistors 302 and 304, the voltage between the source terminal of the differential transistor 304 and the connecting point 306 is larger than the voltage between the source terminal of the differential transistor 302 and the connecting point 306. Thus, assuming that the differential transistors 302 and 304 are in a non-offset state having the same gate voltage, an output voltage of the output circuit 300 is stabilized in a state higher than that of an input voltage to the input terminal 320.

As described above, the output circuit 300 controls the switches 310 connected to the resistors RA2, RA3, RA4, . . . in parallel. In other words, a combined resistance value is changed by changing the number of parallel resistors. Accordingly, the output circuit 300 changes the output voltage.

### SUMMARY OF THE INVENTION

However, in the operational amplifier circuit (output circuit) described in Patent Reference 1, the resistors and switches are connected to the source terminals of the differential transistors. Thereby, parasitic capacitance of the source terminals of the differential transistors increases. As a result, there is a problem that the operating speed of the operational amplifier circuit decreases.

Particularly in recent years, operational amplifier circuits used in display panels need reduction in variation of output voltages, for example, up to several tens of millivolts. As such, in order to adjust the variation of output voltages (input offset voltage) with high precision, the operational amplifier circuit described in Patent Reference 1 needs a larger number of resistors and switches. Thereby, the operating speed of the operational amplifier circuit further decreases.

Thus, the present invention has an object of providing an operational amplifier circuit that can adjust the input offset voltage with high precision while suppressing decrease in the operating speed.

In order to achieve the object, an operational amplifier circuit according to an aspect of the present invention includes: a first input terminal; a second input terminal; an output terminal; a differential amplifier that amplifies a potential difference between the first input terminal and the second input terminal, and outputs, to the output terminal, the amplified difference as an output signal; and a first correction current supply unit configured to supply the differential amplifier with a first correction current to adjust an input offset voltage of the operational amplifier circuit.

With the structure, the operational amplifier circuit according to the aspect of the present invention can adjust the input offset voltage by adjusting a current value to be supplied to the differential amplifier. Thus, the operational amplifier circuit maintains constant the parasitic capacitance even when the precision for adjusting the input offset voltage increases. Thereby, the operational amplifier circuit can adjust the input offset voltage with high precision while suppressing decrease in the operating speed.

Furthermore, the differential amplifier may include: a first differential transistor having a gate terminal connected to the first input terminal; a second differential transistor having a gate terminal connected to the second input terminal, and forming a first differential pair with the first differential transistor; and a first current source transistor that supplies a current to source terminals of the first differential transistor and the second differential transistor, and the first correction current supply unit may be configured to supply the first correction current to a drain terminal of the first differential transistor.

With the structure, the operational amplifier circuit according to the aspect of the present invention can adjust the input offset voltage by adjusting a current value to be supplied to the drain terminal of the first differential transistor. Thus, the operational amplifier circuit maintains constant the parasitic capacitance even when the precision for adjusting the input offset voltage increases. Thereby, the operational amplifier circuit can adjust the input offset voltage with high precision while suppressing decrease in the operating speed.

Furthermore, the differential amplifier may include: a first differential transistor having a base terminal connected to the first input terminal; a second differential transistor having a base terminal connected to the second input terminal, and forming a first differential pair with the first differential transistor; and a first current source transistor that supplies a current to emitter terminals of the first differential transistor and the second differential transistor, wherein the first correction current supply unit may be configured to supply the first correction current to a collector terminal of the first differential transistor.

With the structure, the operational amplifier circuit according to the aspect of the present invention can adjust the input offset voltage by adjusting a current value to be supplied to the collector terminal of the first differential transistor. Thus, the operational amplifier circuit maintains constant the parasitic capacitance even when the precision for adjusting the input offset voltage increases. Thereby, the operational amplifier circuit can adjust the input offset voltage with high precision while suppressing decrease in the operating speed.

Furthermore, the first correction current supply unit may include a first correction transistor that has (i) a drain terminal connected to the drain terminal of the first differential transistor and (ii) a gate terminal to which a first correction voltage signal is applied, the first correction transistor supplying the drain terminal of the first differential transistor with the first correction current having a current value corresponding to a voltage of the first correction voltage signal.

With the structure, in the operational amplifier circuit according to the aspect of the present invention, only a drain terminal of one first correction transistor is connected to the first differential transistor. Thereby, the operational amplifier circuit can adjust the input offset voltage with high precision while suppressing decrease in the operating speed.

Furthermore, the first correction current supply unit may further include a second correction transistor that forms a differential pair with the first correction transistor, has (i) a drain terminal connected to a drain terminal of the second differential transistor and (ii) a gate terminal to which a second correction voltage signal is applied, and supplies the drain terminal of the second differential transistor with a second correction current having a current value corresponding to a voltage of the second correction voltage signal.

With the structure, the operational amplifier circuit according to the aspect of the present invention can adjust the input offset voltage in both positive and negative directions.

Furthermore, each of the first correction transistor and the second correction transistor may be an n-type MOS transistor, and the first correction current supply unit may include a first correction current source transistor that supplies a current to source terminals of the first correction transistor and the second correction transistor.

With the structure, the operational amplifier circuit according to the aspect of the present invention can adjust the input offset voltage by extracting a current from a drain terminal of a differential transistor. Thereby, the operational amplifier circuit can easily adjust the input offset voltage with an adjustment amount, without any occurrence of defect such that, for example, the operational amplifier circuit does not normally operate.

Furthermore, each of the first correction transistor and the second correction transistor may be a p-type MOS transistor, and sources of the first correction transistor and the second correction transistor may be connected to a power supply line to which a supply voltage is applied.

With the structure, the operational amplifier circuit according to the aspect of the present invention can adjust the input offset voltage by applying a current to a drain terminal of a differential transistor. Thereby, the operational amplifier circuit can adjust the input offset voltage while suppressing decrease in gain of the operational amplifier circuit.

Furthermore, the operational amplifier circuit may further include a stop control unit configured to stop supplying the first correction current from the first correction current supply unit to the differential amplifier during a predetermined period from a time when the potential difference between the first input terminal and the second input terminal is changed.

With the structure, the operational amplifier circuit according to the aspect of the present invention can improve the operating speed.

Furthermore, the operational amplifier circuit may further include a comparing and determining unit configured to detect a difference between a current that flows through the first differential transistor and a current that flows through the second differential transistor, the first differential transistor and the second differential transistor being included in the differential amplifier, and forming a differential pair, wherein the first correction current supply unit may be configured to generate the first correction current for correcting the detected difference in current.

Furthermore, a signal driver according to an aspect of the present invention is a signal driver that drives input signals and outputs output signals corresponding to the driven input signals, and includes: operational amplifier circuits each provided to a correspond one of the input signals, each of the operational amplifier circuits having (i) a non-inverting input terminal that receives a corresponding one of the input signals and (ii) an inverting input terminal connected to the output terminal, and outputting, to the output terminal, a corresponding one of the output signals, the non-inverting input terminal being one of the first input terminal and the second input terminal, and the inverting input terminal being the other of the first input terminal and the second input terminal; a voltage generating unit configured to generate voltage signals having different voltage values; and selecting units each provided to a corresponding one of said operational amplifier circuits, and configured to select one of the voltage signals, and to output the selected voltage signal as a first correction voltage signal to a corresponding one of said operational amplifier circuits.

With the structure, a common voltage generating unit included in the signal driver according to the aspect of the present invention can generate voltage signals to be supplied to the operational amplifier circuits. Thereby, the signal driver can reduce the circuit area.

Furthermore, the signal driver may have a normal operation mode for driving each of the input signals, and an adjustment mode for adjusting the input offset voltage of each of the operational amplifier circuits, the signal driver may further include storage units each provided to a corresponding one of the operational amplifier circuits, and in each of which setting information for specifying one of the voltage signals is stored, each of the selecting units may be configured to select, in the normal operation mode, the one of the voltage signals specified by the setting information stored in a corresponding one of the storage units, the signal driver may further include: a control unit configured to control, in the adjustment mode, each of the selecting units to sequentially select one of the voltage signals; and a comparing and determining unit configured to compare the output signals with the input signals, and in the adjustment mode, the control unit may be configured to: determine, for each of the operational amplifier circuits, one of the voltage signals so that the input offset voltage of a corresponding one of the operational amplifier circuits is in a predetermined range, using a result of comparison for each of the voltage signals selected by the selecting units, the comparison being performed by the comparing and determining unit; and store the setting information specifying the determined voltage signal in one of the storage units corresponding to the operational amplifier circuit.

With the structure, the operational amplifier circuit according to the aspect of the present invention can automatically adjust an input offset voltage of the operational amplifier circuit.

Furthermore, the signal driver may further include: a latch address control circuit that converts, into parallel data items, serial data received from outside of the signal driver; a latch circuit that latches the parallel data items as latched data items; a level shift circuit that converts voltage levels of the latched data items to generate conversion data items; and a digital-analog (DA) converter circuit that converts the conversion data items into the input signals that are analog signals.

Furthermore, a display device according to an aspect of the present invention is a display device including the signal driver, and includes: a display unit configured to display images corresponding to the output signals output from the signal driver; and a mode control unit configured to set the signal driver to the adjustment mode during a non-display period in which the display unit does not display the images.

With the structure, the display device according to the aspect of the present invention can automatically adjust an input offset voltage during when no image is displayed.

Furthermore, a display device according to an aspect of the present invention is a display device including the signal driver, and includes a display unit configured to display images corresponding to the output signals output from the signal driver, wherein the display unit includes liquid crystal cells or organic electroluminescence (EL) cells that emit light according to the output signals.

Furthermore, an offset voltage adjusting method according to an aspect of the present invention is an offset voltage adjusting method for an operational amplifier circuit including a differential amplifier that drives an input signal and outputs an output signal corresponding to the driven input signal, and the method includes: detecting a difference between a current that flows through a first differential transistor and a current that flows through a second differential transistor by detecting a voltage difference between the input signal and the output signal, the first differential transistor and the second differential transistor being included in the differential amplifier, and forming a differential pair; and generating a correction current for correcting the detected difference in current.

Thereby, with the offset voltage adjusting method according to the aspect of the present invention, a difference between a current that flows through the first differential transistor and a current that flows through the second differential transistor that is caused by manufacturing variation is detected, and a correction current for correcting the difference in current is generated. Thus, with the offset voltage adjusting method, the input offset voltage is adjusted by supplying the differential amplifier with the correction current. Thus, with the offset voltage adjusting method, the parasitic capacitance can be maintained constant even when the precision for adjusting the input offset voltage increases. Thereby, with the offset voltage adjusting method, the input offset voltage can be adjusted with high precision while suppressing decrease in the operating speed.

The present invention can be implemented not only as such an operational amplifier circuit, a signal driver, and a display device but also as (i) a method of controlling an operational amplifier circuit, a signal driver, or a display device or (ii) a method of adjusting an input offset voltage of an operational amplifier circuit, using a part of characteristic units included in the operational amplifier circuit, the signal driver, or the display device as steps, or as a program causing a computer to execute such characteristic steps. It is obvious that such a program can be distributed using recording media, such as a CD-ROM and via transmission media, such as the Internet.

The present invention can be implemented as a semiconductor integrated circuit (LSI) that achieves a part or an entire of the functions of such an operational amplifier circuit.

Thus, the present invention can provide an operational amplifier circuit that can adjust an input offset voltage with high precision while suppressing decrease in the operating speed.

### FURTHER INFORMATION ABOUT TECHNICAL BACKGROUND TO THIS APPLICATION

The disclosure of Japanese Patent Application No. 2010-020669filed on Feb. 1, 2010 including specification, drawings and claims is incorporated herein by reference in its entirety.

The disclosure of PCT application No. PCT/JP2010/006486 filed on Nov. 4, 2010, including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 illustrates a block diagram of a configuration of a display device according to Embodiment 1;

FIG. 2 is a circuit diagram illustrating a structure of a pixel circuit according to Embodiment 1;

FIG. 3 is a block diagram illustrating a structure of a source driver according to Embodiment 1;

FIG. 4 is a block diagram illustrating a structure of a latch address control circuit, a latch circuit, a level shift circuit, and a DA converter circuit according to Embodiment 1;

FIG. 5 is a block diagram illustrating a structure of a source driver according to Embodiment 1;

FIG. 6 is a block diagram illustrating a structure of an operational amplifier circuit according to Embodiment 1;

FIG. 7 is a circuit diagram illustrating a structure of an operational amplifier circuit according to Embodiment 1;

FIG. 8A illustrates an example of an image according to Embodiment 1;

FIG. 8B illustrates an example of an image according to Embodiment 1,

FIG. 9 is a circuit diagram illustrating a structure of a modified example of an operational amplifier circuit according to Embodiment 1;

FIG. 10 is a circuit diagram illustrating a structure of a modified example of an operational amplifier circuit according to Embodiment 1;

FIG. 11 illustrates a structure of a voltage generating unit according to Embodiment 1;

FIG. 12 is a block diagram illustrating a structure of a source driver according to Embodiment 2;

FIG. 13 is a circuit diagram illustrating a structure of an operational amplifier circuit according to Embodiment 2;

FIG. 14 is a block diagram illustrating a structure of a modified example of a source driver according to Embodiment 2;

FIG. 15 is a circuit diagram illustrating a structure of a first voltage generating circuit according to Embodiment 2;

FIG. 16 illustrates a circuit diagram illustrating a structure of an operational amplifier circuit according to Embodiment 3;

FIG. 17 illustrates a circuit diagram illustrating a structure of an active load unit and an output unit according to Embodiment 3;

FIG. 18 is a block diagram illustrating a structure of a source driver according to Embodiment 4;

FIG. 19 is a block diagram illustrating a structure of a source driver according to Embodiment 4;

FIG. 20 is a flowchart of processes of adjusting an input offset voltage by a source driver according to Embodiment 4;

FIG. 21 is a flowchart of processes of adjusting an input offset voltage by a source driver according to Embodiment 4;

FIG. 22 is a block diagram illustrating a structure of a source driver according to Embodiment 5;

FIG. 23 is a flowchart of processes of adjusting an input offset voltage by a source driver according to Embodiment 5;

FIG. 24 is a block diagram illustrating a structure of a modified example of a source driver according to Embodiment 5;

FIG. 25 is a block diagram illustrating a structure of a source driver according to Embodiment 6;

FIG. 26 is a flowchart of processes of adjusting an input offset voltage by a source driver according to Embodiment 6;

FIG. 27 is a timing chart illustrating processes of adjusting a source driver according to Embodiment 6;

FIG. 28 is a block diagram illustrating a structure of a source driver according to Embodiment 7;

FIG. 29 is a flowchart of processes of adjusting an input offset voltage by a source driver according to Embodiment 7;

FIG. 30 is a timing chart illustrating processes of adjusting an input offset voltage by a source driver according to Embodiment 7;

FIG. 31 is a block diagram illustrating a structure of a modified example of a source driver according to the present invention;

FIG. 32 is a flowchart of a method of adjusting an input offset voltage according to the present invention;

FIG. 33 illustrates a circuit diagram illustrating a structure of an operational amplifier circuit according to Embodiment 8;

FIG. 34 is a block diagram illustrating a structure of a source driver according to Embodiment 8;

FIG. 35 illustrates an example of a stop control signal according to Embodiment 8;

FIG. 36 illustrates an example of an output signal according to Embodiment 8;

FIG. 37 is a circuit diagram illustrating a structure of a modified example of an operational amplifier circuit according to Embodiment 8;

FIG. 38 illustrates a circuit diagram illustrating a structure of an operational amplifier circuit according to Embodiment 9;

FIG. 39 is a graph for describing the problems according to Embodiment 10;

FIG. 40 illustrates a circuit diagram illustrating a structure of an operational amplifier circuit according to Embodiment 10;

FIG. 41 is a block diagram illustrating a structure of a source driver according to Embodiment 10;

FIG. 42 illustrates operations performed by an operational amplifier circuit according to Embodiment 10;

FIG. 43 is a circuit diagram illustrating a structure of a modified example of an operational amplifier circuit according to Embodiment 10;

FIG. 44 is a circuit diagram illustrating a structure of an operational amplifier circuit using bipolar transistors according to the present invention;

FIG. 45 is a circuit diagram illustrating a structure of an operational amplifier circuit using bipolar transistors according to the present invention;

FIG. 46 is a circuit diagram illustrating a structure of an operational amplifier circuit using bipolar transistors according to the present invention; and

FIG. 47 illustrates a structure of a conventional output circuit.

### DESCRIPTION OF THE PREFERRED EMBODIMENTS

Embodiments of an operational amplifier circuit according to the present invention will be described with reference to drawings.

### Embodiment 1

An operational amplifier circuit according to Embodiment 1 adjusts an input offset voltage by supplying a current to a drain terminal of a differential transistor. Thus, even when the precision for adjusting the input offset voltage increases, the operational amplifier circuit according to Embodiment 1 can maintain constant the parasitic capacitance. Thereby, the operational amplifier circuit according to Embodiment 1 can adjust the input offset voltage with high precision while suppressing decrease in the operating speed.

First, a structure of a display device including the operational amplifier circuit according to Embodiment 1 will be described.

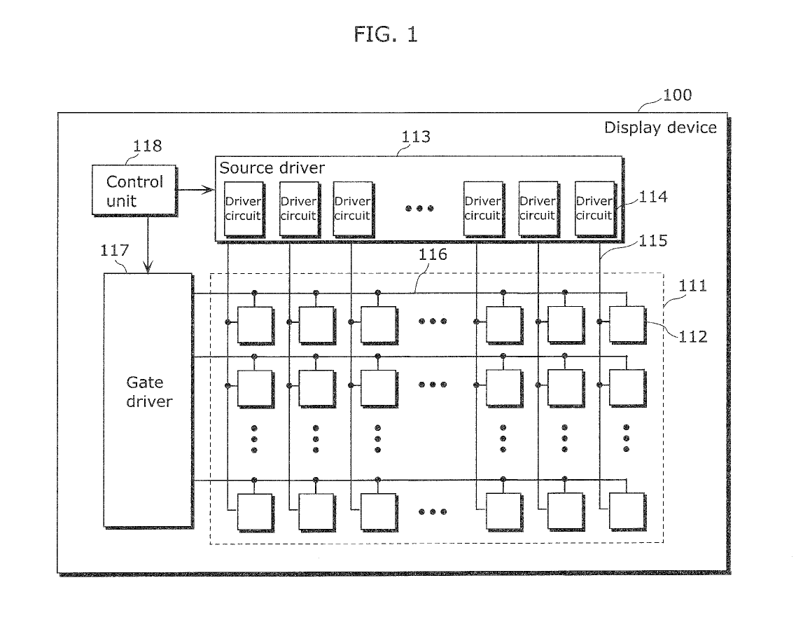

FIG. 1 illustrates a block diagram of a configuration of a display device 100 according to Embodiment 1.

The display device 100 in FIG. 1 displays an image according to an input image signal. The display device 100 includes a display unit 111, a source driver 113, a gate driver 117, and a control unit 118.

The display unit 111 is a display panel that displays an image according to an image signal. The display unit 111 includes pixel circuits 112 arranged in columns and rows, source lines 115 provided for each of the columns, and gate lines 116 provided for each of the rows.

Here, the number of the columns of the display unit 111 is assumed to be N.

The source driver 113 drives the source lines 115 to have voltage values corresponding to an image signal. The source driver 113 corresponds to a signal driver according to the present invention. Furthermore, the source driver 113 includes N driver circuits 114 each of which is provided for a corresponding one of the columns.

The gate driver 117 drives the gate lines 116.

The control unit 118 controls timing when the source driver 113 and the gate driver 117 drive the source lines 115 and the gate line 116, respectively.

Each of the pixel circuits 112 is, for example, liquid crystal cells or organic EL cells. Each of the pixel circuits 112 emits light according to a voltage value or a current value of a corresponding one of the source lines 115, when a corresponding one of the gate lines 116 is selected.

Although the display device 100 in FIG. 1 includes the single source driver 113 and the single gate driver 117, it may include source drivers 113 and gate drivers 117.

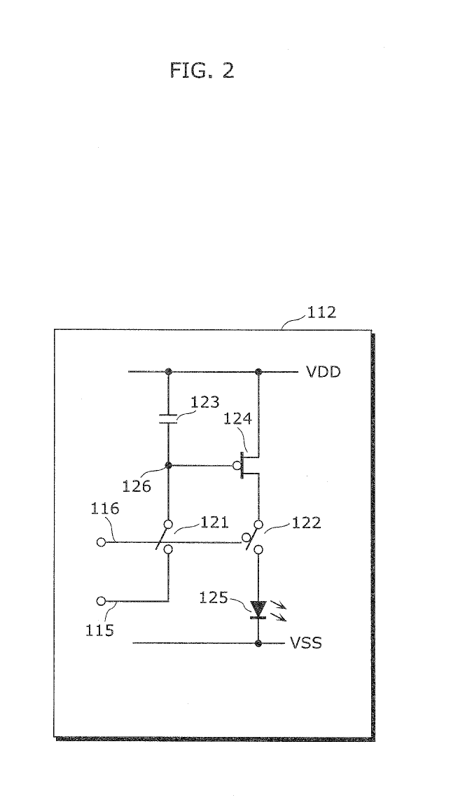

FIG. 2 is a circuit diagram illustrating a structure of the pixel circuit 112.

The pixel circuit 112 in FIG. 2 includes switches 121 and 122, a capacitor 123, a transistor 124, and a luminescent element 125.

ON/OFF of the switches 121 and 122 are controlled according to a signal from the gate line 116. Furthermore, the switch 121 is connected between a node 126 and the source line 115. The switch 122 is connected between one end of the luminescent element 125 and a drain terminal of the transistor 124.

The capacitor 123 is connected between the node 126 and a power supply line to which a supply voltage VDD is applied.

The transistor 124 has a gate terminal connected to the node 126, a source terminal connected to the power supply line, and the drain terminal connected to one end of the switch 122.

The luminescent element 125 is connected between the other end of the switch 122 and a ground potential line to which a ground potential VSS is applied. The luminescent element 125 is, for example, a liquid crystal element or an organic EL element. Although it is assumed that the ground potential VSS is applied to the ground potential line in this description, any voltage smaller than the supply voltage VDD may be applied to the ground potential line.

Next, a structure of the source driver 113 will be described.

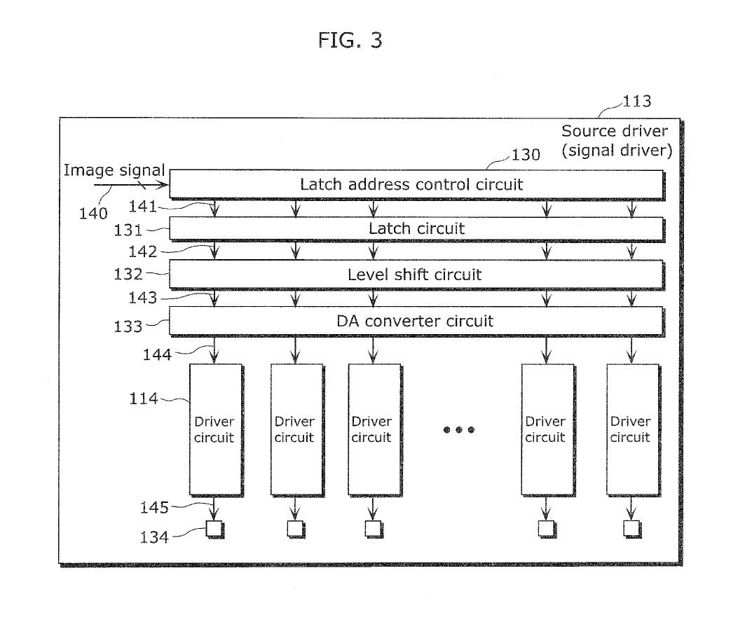

FIG. 3 illustrates the structure of the source driver 113.

As illustrated in FIG. 3, the source driver 113 includes a latch address control circuit 130, a latch circuit 131, a level shift circuit 132, a digital-analog (DA) converter circuit 133, the N driver circuits 114, and N output terminals 134.

The latch address control circuit 130 converts an image signal 140 that is serial data into N parallel data items 141. More specifically, the image signal 140 includes image data items serially input and each having bits. Furthermore, each of the image data items is a display data item of one pixel. Furthermore, each of the N parallel data items 141 corresponds to the display data item of one pixel.

The latch circuit 131 latches (holds) the N parallel data items 141, and outputs the latched N parallel data items 141 as N latched data items 142.

The level shift circuit 132 converts voltage levels of the N latched data items 142 to generate N conversion data items 143.

The DA converter circuit 133 converts the N conversion data items 143 into N input signals 144 that are analog signals.

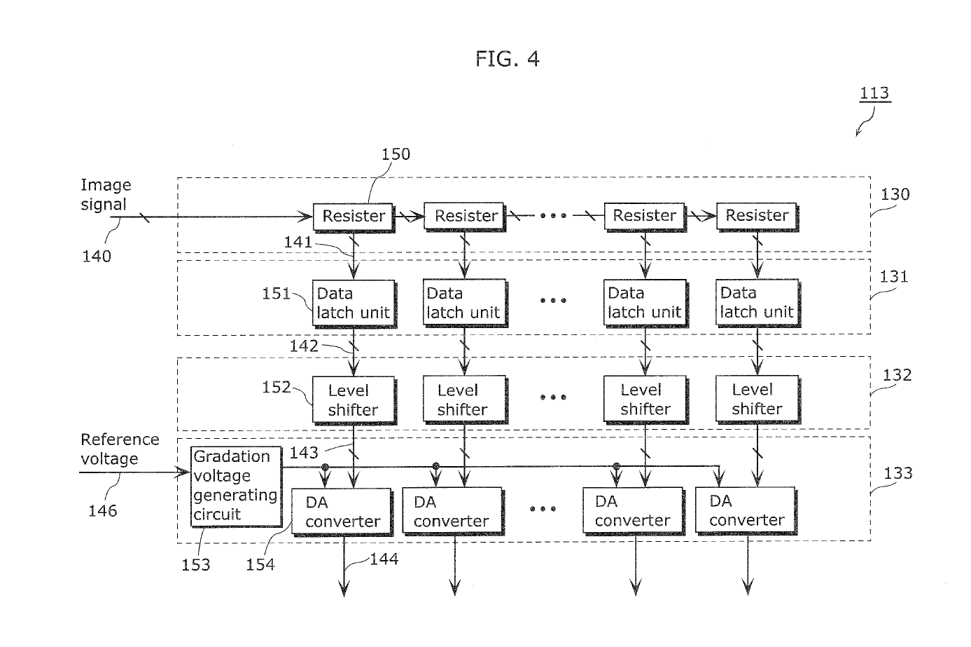

FIG. 4 is a block diagram illustrating a detailed structure of the latch address control circuit 130, the latch circuit 131, the level shift circuit 132, and the DA converter circuit 133.

The latch address control circuit 130 is a shift resister, and includes N resisters 150 that are connected in series.

The latch circuit 131 includes N data latch units 151 provided for each of the columns. Each of the data latch units 151 latches the parallel data item 141 in a corresponding column, and outputs the latched parallel data item 141 as the latched data item 142.

The level shift circuit 132 includes N level shifters 152 provided for each of the columns. Each of the level shifters 152 converts a voltage level of the latched data item 142 in a corresponding column to generate the conversion data item 143. For example, the latched data item 142 is a digital signal of 0 V or 3 V, and the conversion data item 143 is a digital signal of 0 V or 10 V.

The DA converter circuit 133 includes a gradation voltage generating circuit 153 and N DA converters 154.

The gradation voltage generating circuit 153 generates gradation voltages using a reference voltage 146. Furthermore, the gradation voltages correspond to digital values indicated by the conversion data items 143 having bits.

Each of the DA converters 154 outputs one of the gradation voltages that corresponds to a digital value indicated by the conversion data item 143 in a corresponding column, as the input signal 144.

Furthermore, each of the N driver circuits 114 is provided for a corresponding one of the columns as illustrated in FIG. 3.

Although an example is given in which one driver circuit 114 is provided for each of the columns for simplification of the description, in recent years, a selective drive method has been used so that one driver circuit sequentially drives columns at a faster rate. Obviously, the present invention is applicable to this method.

Furthermore, each of the driver circuits 114 drives the input signal 144 in a corresponding column, and outputs an output signal 145 corresponding to the driven input signal 144, to a corresponding one of the output terminals 134.

Here, the N output terminals 134 are connected to the N source lines 115.

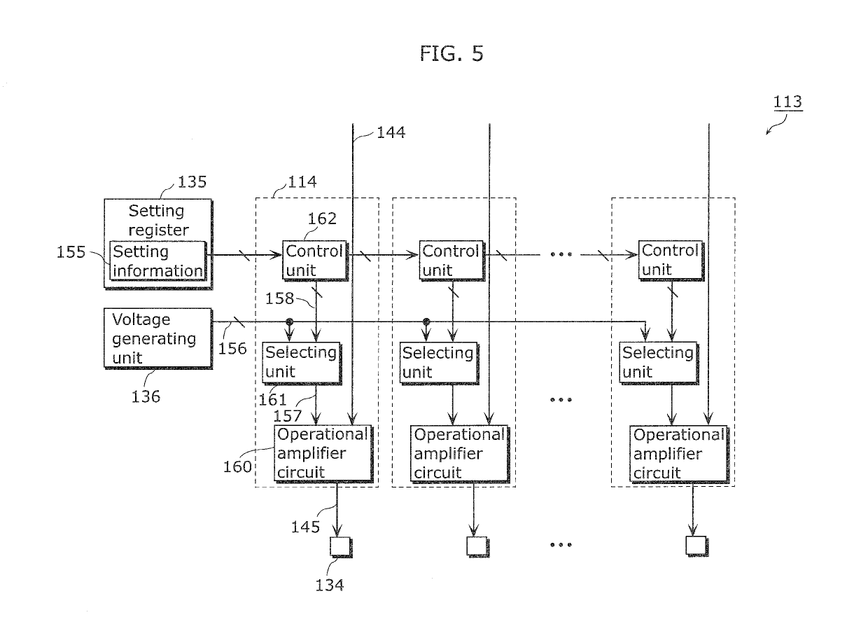

FIG. 5 is a block diagram illustrating a structure of the driver circuits 114.

As illustrated in FIG. 5, the source driver 113 further includes a setting register 135 and a voltage generating unit 136.

Furthermore, each of the driver circuits 114 includes an operational amplifier circuit 160, a selecting unit 161, and a control unit 162.

Each of the operational amplifier circuits 160 drives the input signal 144, and outputs the output signal 145 corresponding to the driven input signal 144, to a corresponding one of the output terminals 134. Furthermore, each of the operational amplifier circuits 160 has a function of adjusting an input offset voltage of the operational amplifier circuit 160, according to a correction voltage signal 157.

The voltage generating unit 136 generates voltage signals 156 having different voltage values.

The setting register 135 holds setting information 155 indicating an adjustment value 158 of an input offset voltage for each of the N operational amplifier circuits 160.

The control unit 162 selects an adjustment value 158 of a corresponding column, from among the adjustment values 158 of the N operational amplifier circuits 160 that are included in the setting information 155. For example, the setting register 135 serially outputs the N adjustment values 158. Furthermore, each of the N control units 162 functions as a shift register to select the adjustment value 158 of the corresponding column.

The selecting unit 161 selects two of the voltage signals 156 indicated by the adjustment value 158 selected by the control unit 162, and outputs the selected two voltage signals 156 as the correction voltage signal 157.

Next, a structure of the operational amplifier circuit 160 will be described.

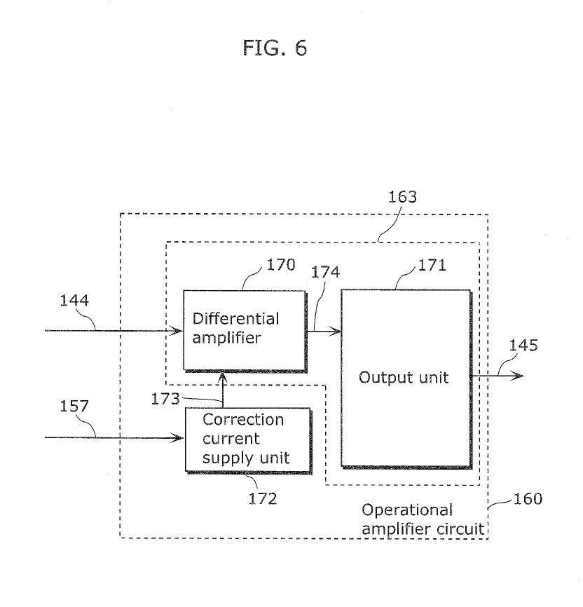

FIG. 6 is a block diagram illustrating the structure of the operational amplifier circuit 160.

The operational amplifier circuit 160 includes an operational amplifier 163 and a correction current supply unit 172. Furthermore, the operational amplifier 163 includes a differential amplifier 170 and an output unit 171.

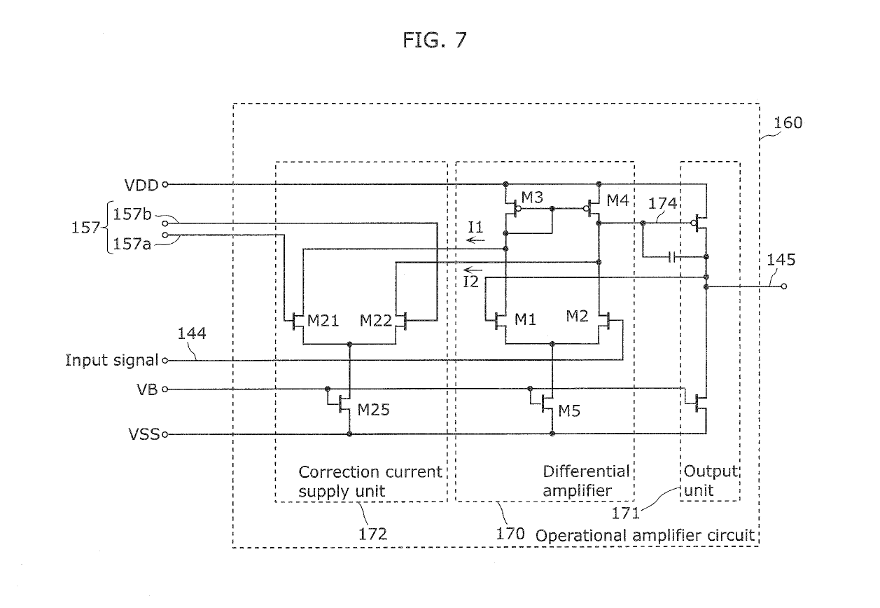

FIG. 7 is a circuit diagram illustrating a detailed structure of the operational amplifier circuit 160.

The operational amplifier circuit 160 is an operational amplifier, and has an inverting input terminal, a non-inverting input terminal, and an output terminal. The operational amplifier circuit 160 amplifies a potential difference between the inverting input terminal and the non-inverting input terminal, and outputs, to the output terminal, the amplified difference as a voltage.

Furthermore, in the operational amplifier circuit 160, the inverting input terminal is connected to the output terminal. Thus, the operational amplifier circuit 160 ideally outputs, to the output terminal, a voltage value input to the non-inverting input terminal.

The differential amplifier 170 generates an amplified signal 174 corresponding to the potential difference between the inverting input terminal and the non-inverting input terminal. The differential amplifier 170 includes differential transistors M1 and M2, a current source transistor M5, and load transistors M3 and M4. For example, each of the differential transistors M1 and M2 and the current source transistor M5 is an n-type MOS transistor, and each of the load transistors M3 and M4 is a p-type MOS transistor.

The differential transistor M1 has a gate terminal connected to the inverting input terminal. The differential transistor M2 has a gate terminal connected to the non-inverting input terminal. Furthermore, the differential transistors M1 and M2 form a differential pair.

The current source transistor M5 supplies a current to source terminals of the differential transistors M1 and M2. More specifically, the current source transistor M5 has a gate terminal connected to a voltage line to which a bias voltage VB is applied, a source terminal connected to the ground potential line to which the ground potential VSS is applied, and a drain terminal connected to the source terminals of the differential transistors M1 and M2.

The output unit 171 outputs the output signal 145 corresponding to the amplified signal 174, to the output terminal.

Since the circuit structure of the differential amplifier 170 and the output unit 171 in FIG. 7 is an example, a circuit structure of a known operational amplifier may be used as the circuit structure.

The correction current supply unit 172 supplies the differential amplifier 170 with a correction current 173 in order to adjust an input offset voltage of the operational amplifier circuit 160.

Here, the correction current 173 includes correction currents I1 and I2. Furthermore, the correction voltage signal 157 output from the selecting unit 161 includes correction voltage signals 157a and 157b.

The correction current supply unit 172 supplies a drain terminal of the differential transistor M1 with the correction current I1 having a current value corresponding to a voltage of the correction voltage signal 157a. Furthermore, the correction current supply unit 172 supplies a drain terminal of the differential transistor M2 with the correction current I2 having a current value corresponding to a voltage of the correction voltage signal 157b. Here, supplying a current implies both applying and extracting currents.

The correction current supply unit 172 includes correction transistors M21 and M22 and a current source transistor M25. Each of the correction transistors M21 and M22 and the current source transistor M25 is, for example, an n-type MOS transistor.

The correction transistor M21 has a gate terminal to which the correction voltage signal 157a is applied, and a drain terminal connected to the drain terminal of the differential transistor M1.

The correction transistor M22 has a gate terminal to which the correction voltage signal 157b is applied, and a drain terminal connected to the drain terminal of the differential transistor M2.

The current source transistor M25 supplies a current to source terminals of the correction transistors M21 and M22. More specifically, the current source transistor M25 has a gate terminal connected to the voltage line to which the bias voltage VB is applied, a source terminal connected to the ground potential line, and a drain terminal connected to the source terminals of the correction transistors M21 and M22.

With the structure, the operational amplifier circuit 160 according to Embodiment 1 can adjust an input offset voltage. Here, the input offset voltage is an offset voltage caused by manufacturing variation between the differential transistors M1 and M2. More specifically, as described above, the operational amplifier circuit 160 ideally outputs the output signal 145 having the same voltage value as that of the input signal 144. However, the voltage value of the output signal 145 is different from the voltage value of the input signal 144 due to the influence of the manufacturing variation. The difference is identical to the input offset voltage. In other words, the input offset voltage is a potential difference between the inverting input terminal and the non-inverting input terminal when a negative feedback loop is formed.

More specifically, the differential transistors M1 and M2 have a difference in threshold voltage due to the influence of the manufacturing variation. Thus, currents flowing through the differential transistors M1 and M2 differ in amount. Thereby, the amplified signal 174 has an error. As a result, the output signal 145 has an error.

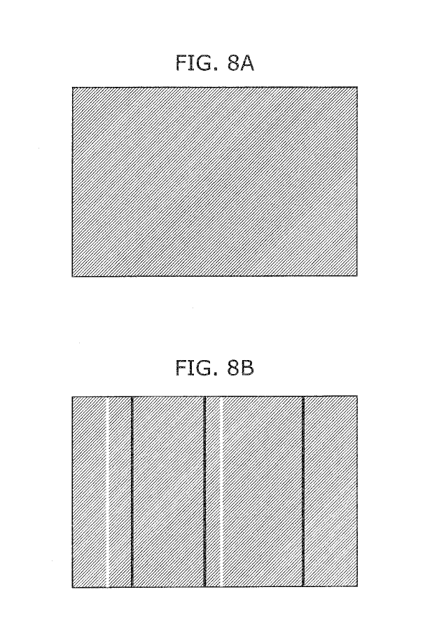

When the input offset voltage is larger, a display device displays an image different from the image that is originally to be displayed. The case will be described hereinafter using an example in which all pixels are used for representing a gray image as illustrated in FIG. 8A. When the input offset voltage is larger, vertical-stripe noise occurs as illustrated in FIG. 8B.

In contrast, the operational amplifier circuit 160 according to Embodiment 1 can prevent occurrence of the vertical-stripe noise by adjusting the input offset voltage.

Furthermore, for example, an external device provides the setting information 155 to be held in the setting register 135. Furthermore, a difference between the correction voltage signals 157a and 157b specified by the setting information 155 is approximately identical to the input offset voltage.

More specifically, when the output signal 145 is larger than the input signal 144 by ΔV, the correction voltage signal 157a is set to a voltage smaller than that of the correction voltage signal 157b by ΔV. Similarly, when the output signal 145 is smaller than the input signal 144 by ΔV, the correction voltage signal 157a is set to a voltage larger than that of the correction voltage signal 157b by ΔV.

Furthermore, the voltage values of the correction voltage signals 157a and 157b may be any value as long as they are within a voltage range where the correction transistors M21 and M22 operate, (for example, values equal to or larger than a threshold voltage of the correction transistors M21 and M22).

Furthermore, the differential amplifier 170 in the operational amplifier circuit 160 according to Embodiment 1 is connected only to drain terminals of the two correction transistors M21 and M22. Furthermore, the operational amplifier circuit 160 adjusts an input offset voltage by changing the gate voltages of the correction transistors M21 and M22. Thus, even when the precision for adjusting the input offset voltage increases, the operational amplifier circuit 160 maintains constant the parasitic capacitance. Thereby, the operational amplifier circuit 160 can adjust the input offset voltage with high precision while suppressing decrease in the operating speed.

The following structure may be used as the structure of the correction current supply unit 172.

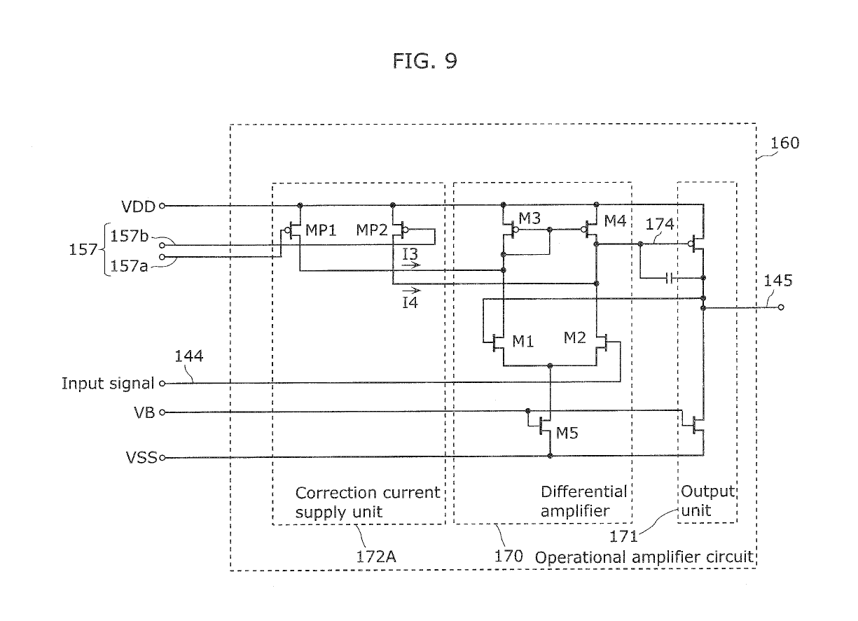

FIG. 9 is a circuit diagram illustrating a structure of a modified example of the operational amplifier circuit 160.

The operational amplifier circuit 160 in FIG. 9 differs in structure of a correction current supply unit 172A from the structure of the correction current supply unit 172 in FIG. 7. The same constituent elements as those in FIG. 7 are denoted by the same reference numerals, in FIG. 9.

The correction current supply unit 172A supplies the differential amplifier 170 with a correction current 173 in order to adjust an input offset voltage of the operational amplifier circuit 160.

Here, the correction current 173 includes correction currents I3 and I4.

The correction current supply unit 172A supplies a drain terminal of a differential transistor M1 with the correction current I3 having a current value corresponding to a voltage of the correction voltage signal 157a. Furthermore, the correction current supply unit 172A supplies a drain terminal of a differential transistor M2 with the correction current I4 having a current value corresponding to a voltage of the correction voltage signal 157b.

The correction current supply unit 172A includes correction transistors MP1 and MP2. Each of the correction transistors MP1 and MP2 is, for example, a p-type MOS transistor.

The correction transistor MP1 has a gate terminal to which the correction voltage signal 157a is applied, a drain terminal connected to the drain terminal of the differential transistor Ml, and a source terminal connected to the power supply line to which the supply voltage VDD is applied.

The correction transistor MP2 has a gate terminal to which the correction voltage signal 157b is applied, and a drain terminal connected to the drain terminal of the differential transistor M2, and a source terminal connected to the power supply line.

With such a structure, the correction current supply unit 172A can adjust an input offset voltage of the operational amplifier circuit 160 as the correction current supply unit 172 in FIG. 7.

Furthermore, a difference between the correction voltage signals 157a and 157b specified by the setting information 155 in this case is approximately identical to the input offset voltage.

More specifically, when the output signal 145 is larger than the input signal 144 by ΔV, the correction voltage signal 157a is set to a voltage smaller than that of the correction voltage signal 157b by ΔV. Similarly, when the output signal 145 is smaller than the input signal 144 by ΔV, the correction voltage signal 157a is set to a voltage larger than that of the correction voltage signal 157b by ΔV.

Furthermore, the voltage values of the correction voltage signals 157a and 157b may be any value as long as they are within a voltage range where the correction transistors MP1 and MP2 operate, for example, (values equal to or smaller than a voltage value obtained by subtracting, from the supply voltage VDD, the threshold voltage of the correction transistors MP1 and MP2).

Here, the correction current supply unit 172 and the correction current supply unit 172A have the following differences as a result of the comparison.

The correction current supply unit 172 extracts currents from the drain terminals of the differential transistors M1 and M2. In contrast, the correction current supply unit 172A applies currents to the drain terminals of the differential transistors M1 and M2. Thereby, when the correction current supply unit 172A is used, gain of the operational amplifier circuit 160 does not decrease. However, when the correction current supply unit 172 is used, gain of the operational amplifier circuit 160 decreases. As such, the correction current supply unit 172A has an advantage that the gain of the operational amplifier circuit 160 does not decrease when the operational amplifier circuit 160 adjusts the input offset voltage.

As described above, the correction current supply unit 172A applies currents. Thus, when the current values become too large, there is a possibility that the operational amplifier circuit 160 will not operate. In contrast, even when the correction current supply unit 172 extracts a larger current, it is unlikely that the operational amplifier circuit 160 will not operate. Meanwhile, the correction current supply unit 172 limits the correction currents I1 and I2 using the current source transistor M25. Thereby, a case where no current flows through the differential transistors M1 and M2 hardly occurs as long as the relationship between the current source transistor M25 and the current source transistor M5 of the differential amplifier 170 is considered.

Thereby, there is an advantage that a circuit can be easily designed with the correction current supply unit 172.

The operational amplifier circuit 160 may include both the correction current supply units 172 and 172A. Thereby, the gain of the operational amplifier circuit 160 does not decrease, and the circuit can be easily designed. However, compared to the case where the operational amplifier circuit 160 includes one of the correction current supply units 172 and 172A, the circuit area increases when the operational amplifier circuit 160 includes both of them.

In order to suppress decrease in gain of the operational amplifier circuit 160 including the correction current supply unit 172, preferably, the current drive capability of the current source transistor M25 (gate width/length) is lower than that of the current source transistor M5. Furthermore, preferably, the current drive capability of the current source transistor M25 (gate width/length) is approximately one half that of the current source transistor M5.

The following structure may be used as the structure of the correction current supply unit 172.

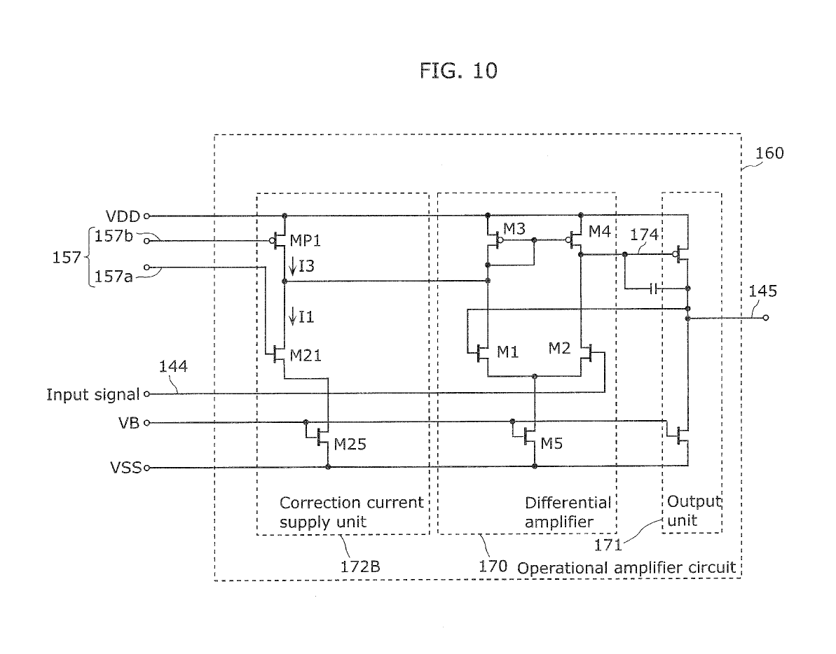

FIG. 10 is a circuit diagram illustrating a structure of a modified example of the operational amplifier circuit 160.

The operational amplifier circuit 160 in FIG. 10 differs in structure of a correction current supply unit 172B from the structure of the correction current supply unit 172 included in the operational amplifier circuit 160 in FIG. 7. The same constituent elements as those in FIG. 7 are denoted by the same reference numerals, in FIG. 10.

The correction current supply unit 172B supplies the differential amplifier 170 with the correction current 173 in order to adjust an input offset voltage of the operational amplifier circuit 160.

The correction current supply unit 172B supplies a drain terminal of the differential transistor M1 with the correction current I1 having a current value corresponding to a voltage of the correction voltage signal 157a. Furthermore, the correction current supply unit 172B supplies the drain terminal of the differential transistor M1 with the correction current I3 having a current value corresponding to a voltage of the correction voltage signal 157b. In other words, the correction current supply unit 172B supplies the drain terminal of the differential transistor M1 with a difference between the correction currents I1 and I3.

The correction current supply unit 172B includes correction transistors M21 and MP1, and a current source transistor M25. Each of the correction transistor M21 and the current source transistor M25 is, for example, an n-type MOS transistor. Furthermore, the correction transistor MP1 is, for example, a p-type MOS transistor.

The correction transistor M21 has a gate terminal to which the correction voltage signal 157a is applied, and a drain terminal connected to the drain terminal of the differential transistor M1.

The current source transistor M25 supplies a current to a source terminal of the correction transistor M21. More specifically, the current source transistor M25 has a gate terminal connected to the voltage line to which the bias voltage VB is applied, a source terminal connected to the ground potential line, and a drain terminal connected to the source terminal of the correction transistor M21.

The correction transistor MP1 has a gate terminal to which the correction voltage signal 157b is applied, a drain terminal connected to the drain terminal of the differential transistor M1, and a source terminal connected to the power supply line.

With such a structure, the correction current supply unit 172B can adjust an input offset voltage of the operational amplifier circuit 160 as the correction current supply unit 172 in FIG. 7.

Furthermore, the correction voltage signals 157a and 157b are set to respective voltage values according to the setting information 155 so that a difference between the correction currents I1 and I3 is approximately identical to a difference between current values that flow through the differential transistors M1 and M2 due to manufacturing variation and others.

More specifically, when the output signal 145 is larger than the input signal 144 by ΔV, the correction voltage signals 157a and 157b are set to respective voltage values so that the correction current I3 is larger than the correction current I1. Similarly, when the output signal 145 is smaller than the input signal 144 by ΔV, the correction voltage signals 157a and 157b are set to respective voltage values so that the correction current I3 is smaller than the correction current I1.

Furthermore, the correction current supply unit 172B can extract a current from the drain terminal of the first differential transistor M1, and apply a current thereto. Thereby, the circuit of the correction current supply unit 172B can be easily designed while gain of the operational amplifier circuit 160 does not decrease. Furthermore, the correction current supply unit 172B can suppress increase in circuit area. However, in the correction current supply unit 172B, the first differential transistor M1 has the parasitic capacitance different from that of the second differential transistor M2.

Although the correction current supply unit 172B supplies a current to the drain terminal of the differential transistor M1, it may supply a current to the drain terminal of the differential transistor M2 instead.

Although in FIG. 10, the correction voltage signals 157a and 157b that are different are applied to the gate terminals of the correction transistors M21 and MP1, respectively, the same correction voltage signal may be applied thereto.

Although in FIGS. 7 and 10, each of the correction current supply units 172 and 172B includes the current source transistor M25, each of the correction current supply units 172 and 172B may not include the current source transistor M25, and the source terminal of each of the correction transistors M21 and M22 may be directly connected to the ground potential line or the voltage line to which a bias voltage is applied.

Furthermore, the correction current supply unit 172A in FIG.9 may further include a current source transistor connected between the source terminals of the correction transistors MP1 and MP2 and the power supply line, and the source terminals of the correction transistors MP1 and MP2 may be connected to the power supply line through the current source transistor.

Furthermore, in the source driver 113 according to Embodiment 1, the operational amplifier circuits 160 can share one voltage generating unit 136. Thereby, the source driver 113 can reduce the circuit area.

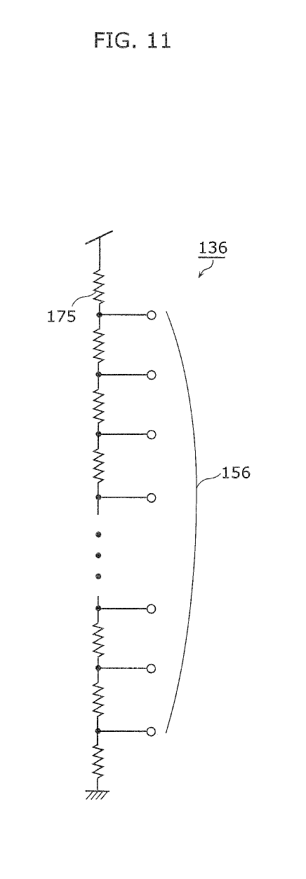

FIG. 11 illustrates a structure of the voltage generating unit 136.

The voltage generating unit 136 includes resistor elements 175 that are connected in series. Furthermore, the voltage generating unit 136 outputs voltages at connecting points of the resistor elements 175, as the voltage signals 156. The resistance values of the resistor elements 175 may be the same or different. In other words, the voltage intervals between the voltage signals 156 may be the same or different.

Furthermore, since the circuit structure for supplying the adjustment values 158 to the selecting units 161 in FIG. 5 is one example, another circuit structure may be used. For example, setting registers for storing the adjustment values 158 corresponding to respective columns may be provided in the circuit structure.

### Embodiment 2

An operational amplifier circuit 160A according to Embodiment 2 includes two correction current supply units at different adjustment intervals. Thereby, the operational amplifier circuit 160A can have a wider adjustment range of input offset voltages while suppressing increase in the circuit area.

The differences with the operational amplifier circuit 160 according to Embodiment 1 will be mainly described hereinafter.

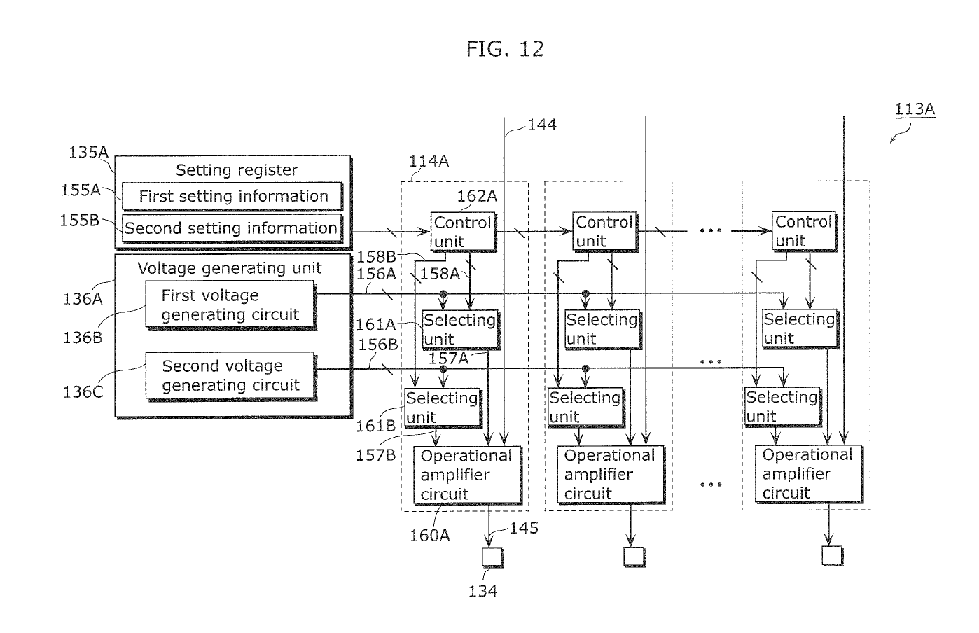

FIG. 12 is a block diagram illustrating a structure of a source driver 113A according to Embodiment 2.

As illustrated in FIG. 12, the source driver 113A includes a setting register 135A and a voltage generating unit 136A.

Furthermore, each driver circuit 114A includes an operational amplifier circuit 160A, selecting units 161A and 161B, and a control unit 162A.

Each of the operational amplifier circuits 160A drives an input signal 144, and outputs an output signal 145 corresponding to the driven input signal 144, to an output terminal 134. Furthermore, each of the operational amplifier circuits 160A has a function of adjusting an input offset voltage of the operational amplifier circuit 160A, according to correction voltage signals 157A and 157B.

The voltage generating unit 136A generates voltage signals 156A having different voltage values and voltage signals 156B having different voltage values. The voltage generating unit 136A includes a first voltage generating circuit 136B that generates the voltage signals 156A, and a second voltage generating circuit 136C that generates the voltage signals 156B. Furthermore, each of the first voltage generating circuit 136B and the second voltage generating circuit 136C has the same structure as that in FIG. 11, for example.

The setting register 135A holds first setting information 155A and second setting information 155B which indicate adjustment values of input offset voltages of the N operational amplifier circuits 160A.

Each of the control units 162A selects an adjustment value 158A in a corresponding column, from among adjustment values 158A of the N operational amplifier circuits 160A that are included in the first setting information 155A. Furthermore, each of the control units 162A selects an adjustment value 158B in a corresponding column from among adjustment values 158B of the N operational amplifier circuits 160A that are included in the second setting information 1556. For example, the setting register 135A serially outputs the N adjustment values 158A and 158B. Furthermore, each of the N control units 162A functions as a shift register to select the adjustment values 158A and 158B of the corresponding column.

Each of the selecting units 161A selects two of the voltage signals 156A indicated by the adjustment value 158A selected by the control unit 162A, and outputs the selected two voltage signals 156A as the correction voltage signal 157A.

Each of the selecting units 161B selects two of the voltage signals 156B indicated by the adjustment value 158B selected by the control unit 162A, and outputs the selected two voltage signals 156B as the correction voltage signal 157B.

Next, a structure of the operational amplifier circuit 160A will be described.

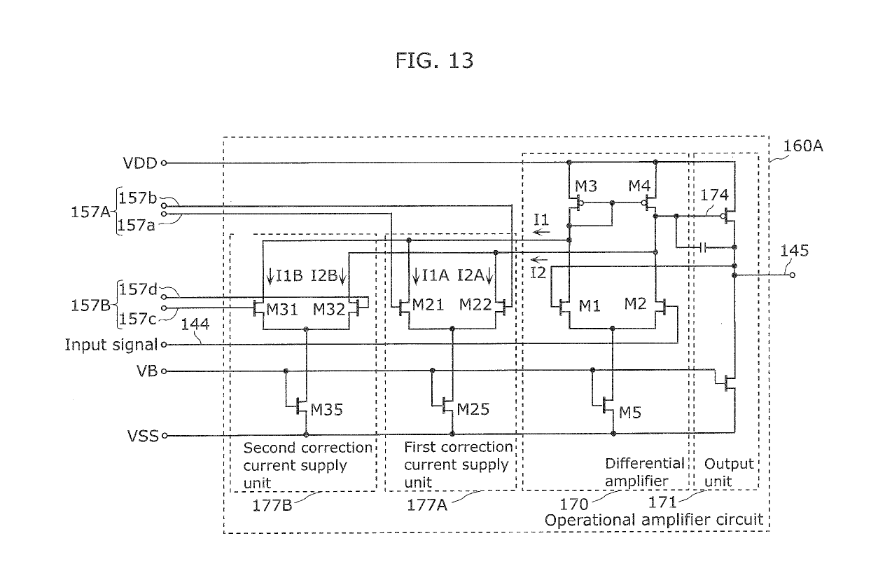

FIG. 13 is a circuit diagram illustrating the structure of the operational amplifier circuit 160A. The same constituent elements as those in FIG. 7 are denoted by the same reference numerals, in FIG. 13.

The operational amplifier circuit 160A includes a differential amplifier 170, an output unit 171, a first correction current supply unit 177A, and a second correction current supply unit 177B. The differential amplifier 170 and the output unit 171 have the same structures as those in FIG. 7.

The first correction current supply unit 177A and the second correction current supply unit 177B supply the differential amplifier 170 with a correction current 173 in order to adjust an input offset voltage of the operational amplifier circuit 160A. Furthermore, the second correction current supply unit 177B adjusts the input offset voltage of the operational amplifier circuit 160A at intervals longer than intervals of adjustment by the first correction current supply unit 177A.

Here, the correction current 173 includes correction currents I1 and I2. Furthermore, the correction voltage signal 157A includes the correction voltage signals 157a and 157b, and the correction voltage signal 157B includes correction voltage signals 157c and 157d.

The first correction current supply unit 177A supplies a drain terminal of the differential transistor M1 with a correction current I1A of a current value corresponding to a voltage of the correction voltage signal 157a. The first correction current supply unit 177A supplies a drain terminal of the differential transistor M2 with a correction current I2A of a current value corresponding to a voltage of the correction voltage signal 157b.

The second correction current supply unit 177B supplies the drain terminal of the differential transistor M1 with a correction current I1B of a current value corresponding to a voltage of the correction voltage signal 157c. Furthermore, the second correction current supply unit 177B supplies the drain terminal of the differential transistor M2 with a correction current I2B of a current value corresponding to a voltage of the correction voltage signal 157d.

In other words, the drain terminal of the differential transistor M1 is supplied with the correction current I1 that is a sum of the correction currents I1A and I1B. Furthermore, the drain terminal of the differential transistor M2 is supplied with the correction current I2 that is a sum of the correction currents I2A and I2B.

Here, each of the first correction current supply unit 177A and the second correction current supply unit 177B has the same structure as that of the correction current supply unit 172 according to Embodiment 1.

More specifically, the first correction current supply unit 177A includes correction transistors M21 and M22 and a current source transistor M25. Furthermore, the second correction current supply unit 177B includes correction transistors M31 and M32 and a current source transistor M35.

The correction transistor M21 has a gate terminal to which the correction voltage signal 157a is applied, and a drain terminal connected to the drain terminal of the differential transistor M1.

The correction transistor M22 has a gate terminal to which the correction voltage signal 157b is applied, and a drain terminal connected to the drain terminal of the differential transistor M2.

The current source transistor M25 supplies a current to source terminals of the correction transistors M21 and M22. More specifically, the current source transistor M25 has a gate terminal connected to the voltage line to which the bias voltage VB is applied, a source terminal connected to the ground potential line, and a drain terminal connected to the source terminals of the correction transistors M21 and M22.

The correction transistor M31 has a gate terminal to which the correction voltage signal 157c is applied, and a drain terminal connected to the drain terminal of the differential transistor M1.

The correction transistor M32 has a gate terminal to which the correction voltage signal 157d is applied, and a drain terminal connected to the drain terminal of the differential transistor M2.

The current source transistor M35 supplies a current to source terminals of the correction transistors M31 and M32. More specifically, the current source transistor M35 has a gate terminal connected to the voltage line to which the bias voltage VB is applied, a source terminal connected to the ground potential line, and a drain terminal connected to the source terminals of the correction transistors M31 and M32.

Here, each of the first correction current supply unit 177A and the second correction current supply unit 177B may have the same structure as that of the correction current supply unit 172A or 172B.

Here, each of the voltage intervals of the voltage signals 156B generated by the second voltage generating circuit 136C is wider than that of the voltage signals 156A generated by the first voltage generating circuit 136B. In other words, the voltage range in which the voltage signals 156B are included is wider than the voltage range in which the voltage signals 156A are included. For example, each of the voltage intervals of the voltage signals 156A is several millivolts, while each of the voltage intervals of the voltage signals 156B is several tens of millivolts.

The input offset modes of the operational amplifier circuit 160A are mainly categorized into the following two modes. The first mode is an input offset mode caused by manufacturing variation and temperature change in the differential transistors M1 and M2. The input offset voltages are of the order of several millivolts.

The second mode is an input offset mode caused by mask misalignment in manufacturing and others. The input offset voltages are of the order of several tens of millivolts.

In the operational amplifier circuit 160A according to Embodiment 2, the first correction current supply unit 177A can correct the input offset voltage of the order of several millivolts, while the second correction current supply unit 177B can correct the input offset voltage of the order of several tens of millivolts.

Thereby, since the operational amplifier circuit 160A can correct the input offset voltage in both of the two modes, the manufacturing yield can be improved.

Compared to the case where one correction current supply unit corrects an input offset voltage, the number of the voltage signals 156A and 156B to be used for the correction can be reduced by correcting the input offset voltage using two correction current supply units. Thereby, the source driver 113A can adjust an input offset voltage in a wider voltage range, with a smaller circuit size.

Although the voltage generating unit 136A includes the first voltage generating circuit 136B and the second voltage generating circuit 136C, the voltage generating unit 136A may include only one voltage generating circuit.

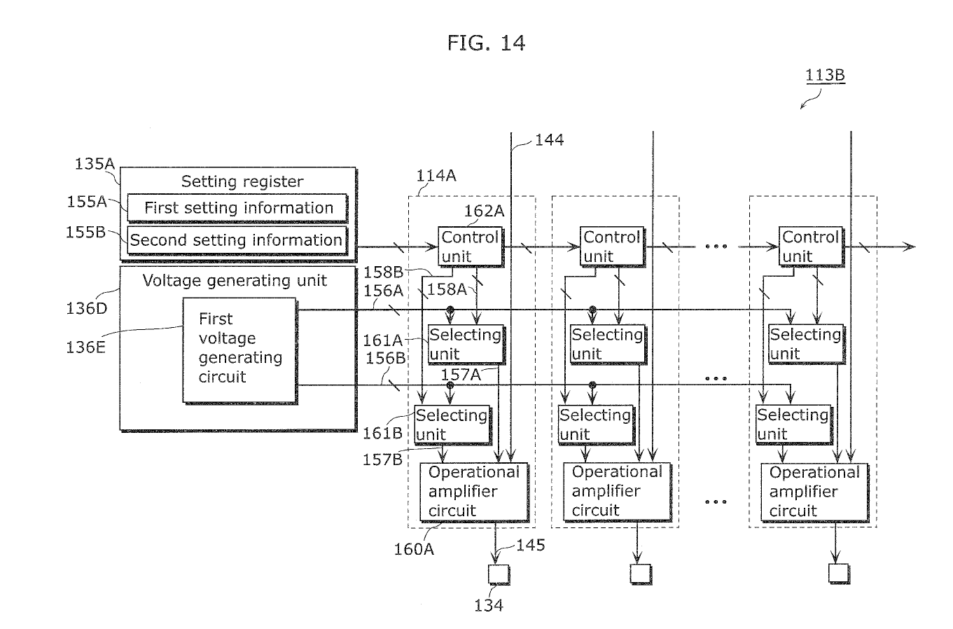

FIG. 14 is a block diagram illustrating a structure of a modified example of the source driver 113A. A structure of a voltage generating unit 136D included in a source driver 113B in FIG. 14 differs from that of the voltage generating unit 136A included in the source driver 113A in FIG. 12.

The voltage generating unit 136D includes a first voltage generating circuit 136E. The first voltage generating circuit 136E generates voltage signals 156A having different voltage values and voltage signals 156B having different voltage values.

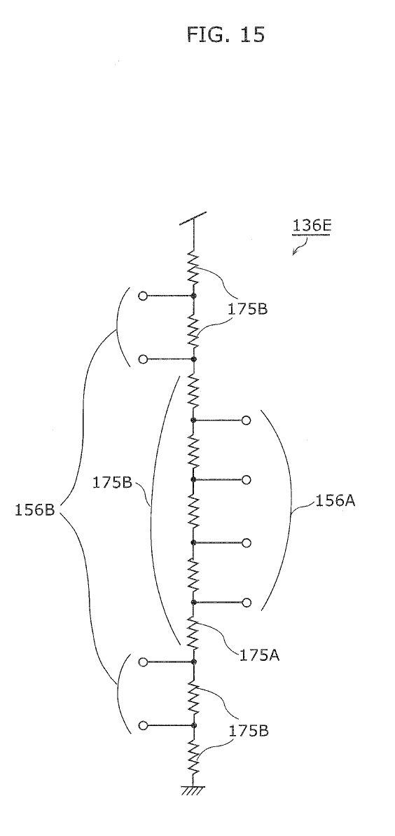

FIG. 15 illustrates a structure of the first voltage generating circuit 136E. As illustrated in FIG. 15, the first voltage generating circuit 136E includes, for example, five second resistor elements 175B that are connected in series. Furthermore, voltages at four connecting points of the five second resistor elements 175B are output as four voltage signals 156B.

Furthermore, one of the five second resistor elements 175B includes five first resistor elements 175A that are connected in series. Furthermore, voltages at four connecting points of the five first resistor elements 175A are output as four voltage signals 156A.

As such, the first voltage generating circuit 136E generates the voltage signals 156A and 156B, using resistor elements at least part of which are shared.

Thereby, the variation characteristics of voltages between the voltage signals 156A and 156B caused by manufacturing variation and change in temperature can be unified.

In contrast, the two independent circuits of the first voltage generating circuit 136B and the second voltage generating circuit 136C included in the voltage generating unit 136A in FIG. 12 generate the voltage signals 156A and the voltage signals 156B, respectively. Thereby, for example, with combined use of the resistor elements in the first voltage generating circuit 136B and the resistor elements in the second voltage generating circuit 136C, different resistor elements (for example, a resistor using a diffusion region, a resistor using a polysilicon line, and a resistor using a high resistance polysilicon line for resistor elements) can be used according to a necessary resistance value and the precision. Thereby, the total area of the resistor elements used by the voltage generating unit 136A can be reduced.

Although FIG. 15 exemplifies the case where the number of each of the voltage signals 156A and 156B is four, the number of the voltage signals 156A and 156B may be other.

Furthermore, although one second resistor element 175B includes all the first resistor elements 175A in FIG. 15, second resistor elements 175B may include the first resistor elements 175A.

### Embodiment 3

Embodiment 3 will describe a case where an operational amplifier circuit uses a Rail-to-Rail (R-R) operational amplifier.

Furthermore, each driver circuit 114A has the same structure as that in FIG. 12.

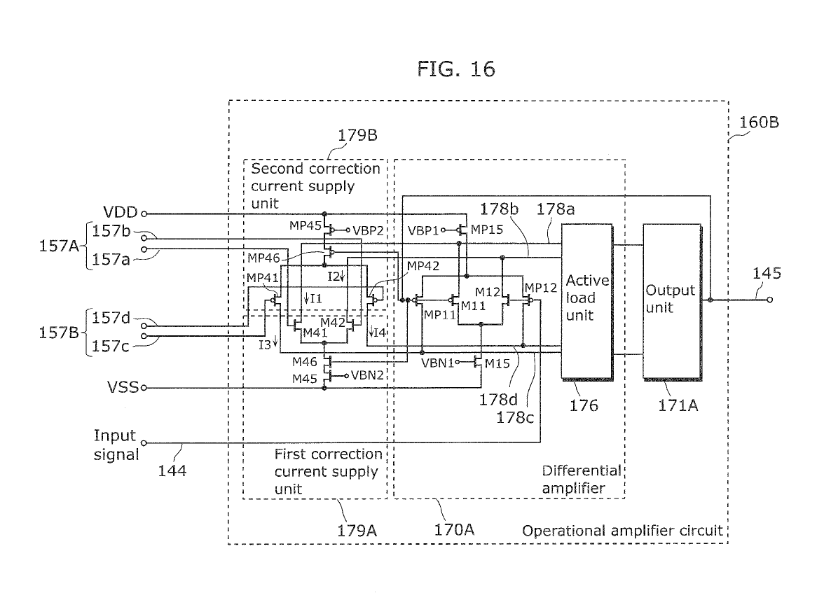

FIG. 16 illustrates a circuit diagram illustrating a structure of an operational amplifier circuit 160B according to Embodiment 3.

The operational amplifier circuit 160B is an R-R operational amplifier, and has an inverting input terminal, a non-inverting input terminal, and an output terminal. Furthermore, the inverting input terminal is connected to the output terminal. Thus, the operational amplifier circuit 160B ideally outputs a voltage input to the non-inverting input terminal, to the output terminal.

Furthermore, the operational amplifier circuit 160B includes a differential amplifier 170A, an output unit 171A, a first correction current supply unit 179A, and a second correction current supply unit 179B

The differential amplifier 170A generates a voltage signal corresponding to a potential difference between the inverting input terminal and the non-inverting input terminal. The differential amplifier 170A includes differential transistors M11, M12, MP11, and MP12, current source transistors M15 and MP15, and an active load unit 176. For example, each of the differential transistors M11, M12, MP11, and the current source transistor M15 is an n-type MOS transistor, and each of the differential transistors MP11 and MP12 and the current source transistor MP15 is a p-type MOS transistor.

The differential transistor M11 has a gate terminal connected to the inverting input terminal. The differential transistor M12 has a gate terminal connected to the non-inverting input terminal. Furthermore, the differential transistors M11 and M12 form a first differential pair. Furthermore the differential transistor M11 has a drain terminal connected to a node 178a. Furthermore the differential transistor M12 has a drain terminal connected to a node 178b.

The current source transistor M15 supplies a current to source terminals of the differential transistors M11 and M12. More specifically, the current source transistor M15 has a gate terminal connected to the voltage line to which a bias voltage VBN1 is applied, a source terminal connected to the ground potential line, and a drain terminal connected to the source terminals of the differential transistors M11 and M12.

The differential transistor MP11 has a gate terminal connected to the inverting input terminal. The differential transistor MP12 has a gate terminal connected to the non-inverting input terminal. Furthermore, the differential transistors MP11 and MP12 form a second differential pair. Furthermore, the differential transistor MP11 has a drain terminal connected to a node 178c. Furthermore, the differential transistor MP12 has a drain terminal connected to a node 178d.

The current source transistor MP15 supplies a current to source terminals of the differential transistors MP11 and MP12. More specifically, the current source transistor MP15 has a gate terminal connected to the voltage line to which a bias voltage VBP1 is applied, a source terminal connected to the ground potential line, and a drain terminal connected to the source terminals of the differential transistors MP11 and MP12.

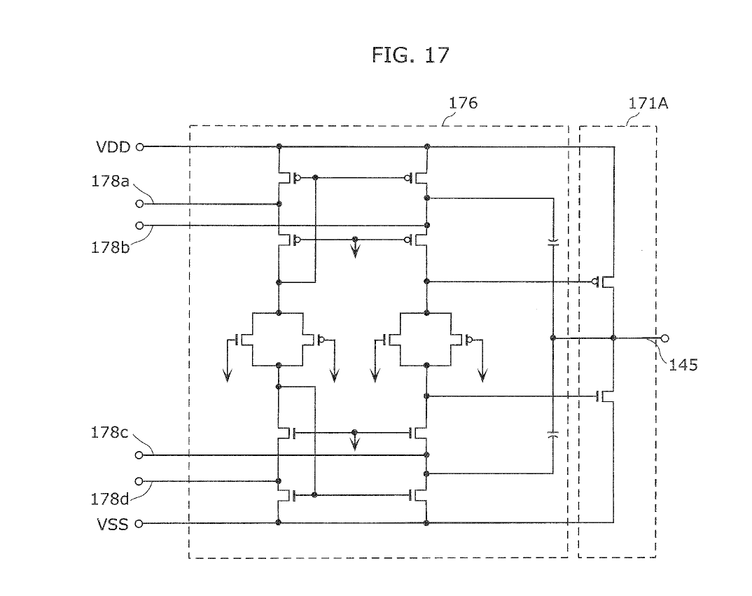

FIG. 17 illustrates a structure of the active load unit 176 and the output unit 171A.

Since the circuit structures of the differential amplifier 170A and the output unit 171A in FIGS. 16 and 17 are examples, a circuit structure of a known R-R operational amplifier may be used as the circuit structure.

The first correction current supply unit 179A and the second correction current supply unit 179B supply the differential amplifier 170A with the correction current 173 in order to adjust an input offset voltage of the operational amplifier circuit 1606.

Here, the correction current 173 includes correction currents I1 to I4. Furthermore, the correction voltage signal 157A includes correction voltage signals 157a and 157b, and the correction voltage signal 157B includes correction voltage signals 157c and 157d.

The first correction current supply unit 179A supplies a first differential pair of the differential transistors M11 and M12 with the correction currents I1 and I2 in order to adjust an input offset voltage of the first differential pair. More specifically, the first correction current supply unit 179A supplies a drain terminal of the differential transistor M11 with the correction current I1 corresponding to a voltage of the correction voltage signal 157a. Furthermore, the first correction current supply unit 179A supplies a drain terminal of the differential transistor M12 with the correction current I2 corresponding to a voltage of the correction voltage signal 157b.

The second correction current supply unit 179B supplies a second differential pair of the differential transistors MP11 and MP12 with the correction currents I3 and I4 in order to adjust an input offset voltage of the second differential pair. More specifically, the second correction current supply unit 179B supplies a drain terminal of the differential transistor MP11 with the correction current I3 corresponding to a voltage of the correction voltage signal 157c. Furthermore, the second correction current supply unit 179B supplies a drain terminal of the differential transistor MP12 with the correction current I4 corresponding to a voltage of the correction voltage signal 157d.

The first correction current supply unit 179A includes correction transistors M41 and M42, a current source transistor M45, and a cut-off transistor M46. Furthermore, the second correction current supply unit 179B includes correction transistors MP41 and MP42, a current source transistor MP45, and a cut-off transistor MP46.

The correction transistor M41 has a gate terminal connected to the correction voltage signal 157a, and a drain terminal connected to the drain terminal of the differential transistor M11.

The correction transistor M42 has a gate terminal connected to the correction voltage signal 157b, and a drain terminal connected to the drain terminal of the differential transistor M12.

The current source transistor M45 supplies a current to source terminals of the correction transistors M41 and M42. More specifically, the current source transistor M45 has a gate terminal connected to the voltage line to which a bias voltage VBN2 is applied and a source terminal connected to the ground potential line.

The cut-off transistor M46 has a gate terminal connected to the inverting input terminal of the operational amplifier circuit 160B, a source terminal connected to the drain terminal of the current source transistor M45, and a drain terminal connected to the source terminals of the correction transistors M41 and M42.

The correction transistor MP41 has a gate terminal to which the correction voltage signal 157c is applied, and a drain terminal connected to the drain terminal of the differential transistor MP11.

The correction transistor MP42 has a gate terminal to which the correction voltage signal 157d is applied, and a drain terminal connected to the drain terminal of the differential transistor MP12.

The current source transistor MP45 supplies a current to source terminals of the correction transistors MP41 and MP42. More specifically, the current source transistor MP45 has a gate terminal connected to the voltage line to which a bias voltage VBP2 is applied, and a source terminal connected to the power supply line.

The cut-off transistor MP46 has the gate terminal connected to the inverting input terminal (output terminal) of the operational amplifier circuit 160B, the source terminal connected to the drain terminal of the current source transistor MP45, and the drain terminal connected to the source terminals of the correction transistors M41 and M42.

With the structure, the operational amplifier circuit 160B according to Embodiment 3 can adjust an input offset voltage of the R-R operational amplifier.

Furthermore, a difference between the correction voltage signals 157a and 157b specified by first setting information 155A is approximately identical to the input offset voltage of the first differential pair (the differential transistors M11 and M12) of the operational amplifier circuit 160B.

Furthermore, a difference between the correction voltage signals 157c and 157d specified by second setting information 155B is approximately identical to the input offset voltage of the second differential pair (the differential transistors MP11 and MP12) of the operational amplifier circuit 160B.

Furthermore, the first correction current supply unit 179A includes the cut-off transistor M46. When the first differential pair (the differential transistors M11 and M12) receives, as an input signal 144, a non-operating voltage (voltage equal to or lower than a threshold voltage of the differential transistors M11 and M12), the cut-off transistor M46 is turned off. Thereby, when the first differential pair does not operate, the first correction current supply unit 179A stops supplying a current.

Furthermore, when the voltage value of the input signal 144 is closer to a region in which the first differential pair does not operate and the current that flows through the first differential pair decreases, the cut-off transistor M46 suppresses the correction currents I1 and I2 according to the decrease in the current.

Similarly, the second correction current supply unit 179B includes the cut-off transistor MP46. When the second differential pair (the differential transistors MP11 and MP12) receives, as the input signal 144, a non-operating voltage (voltage equal to or higher than a voltage obtained by subtracting the threshold voltage of the differential transistors MP11 and MP12 from the supply voltage VDD), the cut-off transistor MP46 is turned off. Thereby, when the second differential pair does not operate, the second correction current supply unit 179B stops supplying a current.

Furthermore, when the voltage value of the input signal 144 is closer to a region in which the second differential pair does not operate and the current that flows through the second differential pair decreases, the cut-off transistor MP46 suppresses the correction currents I3 and I4 according to the decrease in the current.

Thereby, the operational amplifier circuit 160B according to Embodiment 3 can adjust an amount of the correction current according to an operating ratio between the first differential pair and the second differential pair. Thereby, the operational amplifier circuit 160B can supply an appropriate correction current according to the operating ratio between the first differential pair and the second differential pair.

Although the cut-off transistor M46 is connected in series with the current source transistor M45 so that the current source transistor M45 is at the ground potential line side in FIG. 16, the cut-off transistor M46 may be connected in series with the current source transistor M45 so that the cut-off transistor M46 is at the ground potential line side. Similarly, although the cut-off transistor MP46 is connected in series with the current source transistor MP45 so that the current source transistor MP45 is at the power supply line side, the cut-off transistor M46 may be connected in series with the current source transistor M45 so that the cut-off transistor MP46 is at the power supply line side.

Furthermore, although the gate terminals of the cut-off transistors M46 and MP46 are connected to the inverting input terminal of the operational amplifier circuit 160B, they may be connected to the non-inverting input terminal thereof.

Furthermore, although the first correction current supply unit 179A extracts the correction currents I1 and I2 from the differential pair of the differential transistors M11 and M12 in FIG. 16, it may apply a correction current as the correction current supply unit 172A, and may include, as the correction current supply unit 172B, a correction transistor that extracts a correction current from one of the drain terminals of the differential transistors M11 and M12, and a correction transistor that applies a correction current thereto.

Similarly, the second correction current supply unit 179B may extract correction currents from the differential pair of the differential transistors MP11 and MP12, and may include, as the correction current supply unit 172B, a correction transistor that extracts a correction current from one of the drain terminals of the differential transistors MP11 and MP12, and a correction transistor that applies a correction current thereto.

### Embodiment 4

Embodiment 4 describes a source driver 113C having a function of determining an input offset voltage of an operational amplifier circuit and adjusting the input offset voltage.

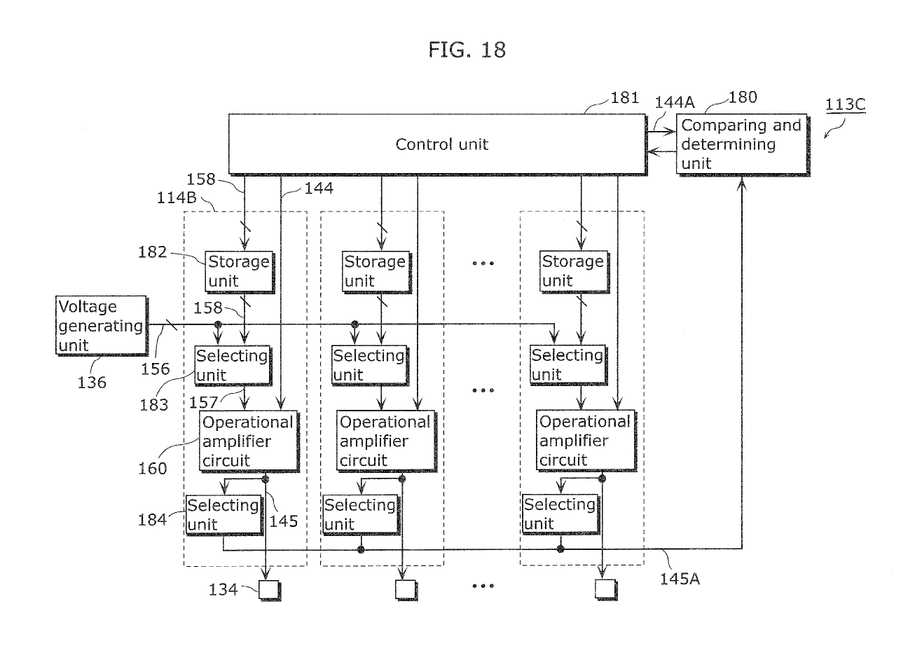

FIG. 18 is a block diagram illustrating a structure of the source driver 113C according to Embodiment 4.

The source driver 113C in FIG. 18 includes a voltage generating unit 136, N driver circuits 114B, a comparing and determining unit 180, and a control unit 181.

Furthermore, each of the driver circuits 114B includes an operational amplifier circuit 160, a storage unit 182, and selecting units 183 and 184.

The structures of the operational amplifier circuits 160 and the voltage generating unit 136 are the same as those according to Embodiment 1.

Each of the storage units 182 stores an adjustment value 158 of an input offset voltage of the operational amplifier circuit 160 in a corresponding column.

Each of the selecting units 183 selects two of voltage signals 156 indicated by the adjustment value 158 stored in the storage unit 182, and outputs the selected two voltage signals 156 as a correction voltage signal 157.

The N selecting units 184 select one of output signals 145 output from the N operational amplifier circuits 160, and output the selected output signal 145 as an output signal 145A.

The comparing and determining unit 180 determines whether the selected output signal 145A is in a first voltage range. Furthermore, the comparing and determining unit 180 compares the selected output signal 145A with a reference voltage 144A specified by the control unit 181, and determines a magnitude relationship between the selected output signal 145A and the reference voltage 144A.

The control unit 181 controls the process of adjusting the input offset voltage. More specifically, the control unit 181 controls the selecting units 183 to sequentially select the voltage signals 156. Furthermore, the control unit 181 updates the adjustment value 158 stored in each of the storage units 182, according to a result of the comparison by the comparing and determining unit 180. Furthermore, the control unit 181 outputs the reference voltage 144A to the comparing and determining unit 180. Furthermore, the control unit 181 controls a column selected by the N selecting units 184.

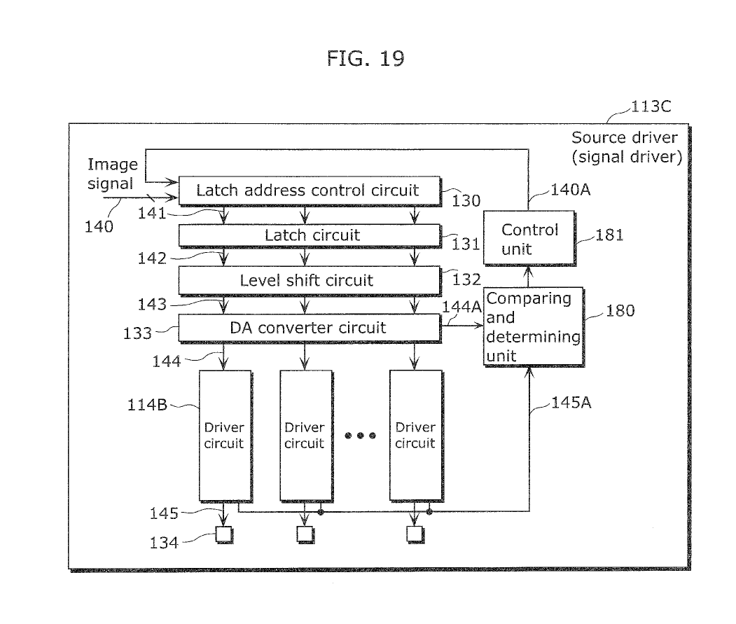

FIG. 19 is a block diagram illustrating an entire structure of the source driver 113C.

More specifically, the control unit 181 generates a reference image signal 140A. A latch address control circuit 130, a latch circuit 131, a level shift circuit 132, and a DA converter circuit 133 sequentially process the reference image signal 140A to generate the reference voltage 144A.

Operations of the source driver 113C will be hereinafter described.

The source driver 113C has a normal operation mode for outputting an output signal according to an image signal 140, and an adjustment mode for adjusting an input offset voltage of each of the operational amplifier circuits 160. For example, the control unit 181 switches between the normal operation mode and the adjustment mode.

First, operations of the source driver 113C in the normal operation mode will be described.

In the normal operation mode, the latch address control circuit 130, the latch circuit 131, the level shift circuit 132, and the DA converter circuit 133 sequentially process the image signal 140 corresponding to display data to generate input signals 144 corresponding to the display data.

Furthermore, each of the selecting units 183 selects two of the voltage signals 156 indicated by the adjustment value 158 stored in the storage unit 182, and outputs the selected two voltage signals 156 as the correction voltage signal 157.

Thereby, each of the operational amplifier circuits 160 generates the output signal 145 by driving the input signal 144 in a state where the input offset voltage is adjusted, and outputs the generated output signal 145 to the output terminal 134.

Thereby, an image corresponding to the image signal 140 is displayed on a display unit 111.

Next, the operations of the source driver 113C in the adjustment mode will be described.

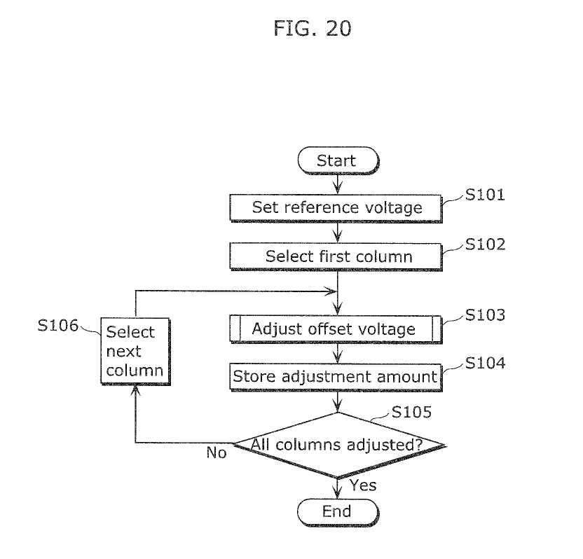

FIG. 20 is a flowchart of operations of the source driver 113C in the adjustment mode.

As illustrated in FIG. 20, first, the control unit 181 sets the reference voltage 144A (S101). The voltage value of the reference voltage 144A may be any value within a voltage range in which the operational amplifier circuit 160 can operate. More specifically, the control unit 181 provides the latch address control circuit 130 with the reference image signal 140A that is a digital signal corresponding to the reference voltage 144A. The latch address control circuit 130, the latch circuit 131, the level shift circuit 132, and the DA converter circuit 133 sequentially process the reference image signal 140A to generate the reference voltage 144A. The reference voltage 144A is provided to both the operational amplifier circuits 160 and the comparing and determining unit 180, as the input signal 144.

Thereby, each of the operational amplifier circuits 160 outputs the output signal 145 obtained by driving the reference voltage 144A with an adjustment amount of the input offset voltage corresponding to the adjustment value 158 stored in the present storage unit 182. The storage unit 182 stores the adjustment value 158 that is predetermined as an initial state (for example, “no adjustment”).

Next, the control unit 181 controls the selecting units 184 to select the output signal 145 of the operational amplifier circuit 160 in the first column (S102).

Next, the source driver 113C adjusts the input offset voltage of the first column (S103). More specifically, the control unit 181 controls the selecting units 183 to sequentially select the voltage signals 156. Furthermore, the control unit 181 determines one of the voltage signals 156 indicating that the input offset voltage of a corresponding one of the operational amplifier circuits 160 is in a predetermined range, using a result of the comparison by the comparing and determining unit 180 for each of the voltage signals 156 selected by the selecting unit 183. The predetermined range may be fixed or dynamically changed according to a state of an image and others.

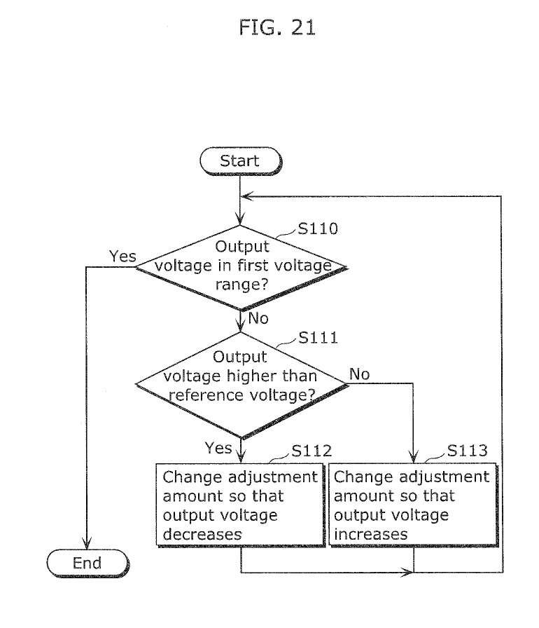

FIG. 21 is a flowchart of processes of adjusting an input offset voltage by the source driver 113C.

First, the comparing and determining unit 180 determines whether or not a voltage of the selected output signal 145A is in a first voltage range (S110). Here, the first voltage range is a predetermined voltage range with respect to the reference voltage 144A. For example, the first voltage range is within a tolerance of ±5 mV from the reference voltage 144A.

When the voltage of the selected output signal 145A is out of the first voltage range (No at S110), next, the comparing and determining unit 180 determines whether or not the voltage of the selected output signal 145A is higher than the reference voltage 144A (S111).

When the voltage of the selected output signal 145A is higher than the reference voltage 144A (Yes at S111), the control unit 181 changes an adjustment amount of the input offset voltage so that the voltage of the output signal 145 decreases, and stores the changed adjustment value 158 as a new adjustment value 158 in each of the storage units 182 (S112). For example, the control unit 181 reduces a value of the correction voltage signal 157a relative to the correction voltage signal 157b (for example, reduces a value of the correction voltage signal 157a without changing the correction voltage signal 157b).

On the other hand, when the voltage of the selected output signal 145A is lower than the reference voltage 144A (No at S111), the control unit 181 changes an adjustment amount of the input offset voltage so that the voltage of the output signal 145 increases, and stores the changed adjustment value 158 as a new adjustment value 158 in each of the storage units 182 (S113). For example, the control unit 181 increases a value of the correction voltage signal 157a relative to the correction voltage signal 157b (for example, increases a value of the correction voltage signal 157a without changing the correction voltage signal 157b).

Next, the operational amplifier circuits 160 output the output signal 145 obtained by driving the reference voltage 144A with an adjustment amount of the input offset voltage corresponding to the adjustment value 158 updated at Step S112 or S113.

Then, the process at S110 is again performed on the selected output signal 145A that is newly output (output signal 145).

As such, until the selected output signal 145A is in the first voltage range, the processes Steps S110 to S113 are repeated.

When the control unit 181 adjusts an input offset voltage using all the programmable adjustment values 158, so that the selected output signal 145A is not within the first voltage range, the control unit 181 notifies, for example, a device outside of the display device of occurrence of an error.

The description will hereinafter proceed with reference to FIG. 20 again.

After Step S103, the control unit 181 stores, in each of the storage units 182, an adjustment amount adjusted at Step S103, as the adjustment value 158 for use in the normal operation mode (S104).

When all the columns are not yet adjusted (No at S105), next, the control unit 181 controls the selecting units 184 to select the output signal 145 of the operational amplifier circuit 160 in the next column (S106), and the processes after Step S103 are performed.

When all the columns have been adjusted (Yes at S105), the control unit 181 ends the adjustment mode and changes to the normal operation mode.

As described above, the source driver 113C according to Embodiment 4 can automatically adjust an input offset voltage of the operational amplifier circuit 160.

Here, the method of adjusting the offset voltage in FIG. 21 is only an example, and other methods may be used. For example, the control unit 181 may sequentially change adjustment amounts in a predetermined order until the voltage of the selected output signal 145A is in the first voltage range. Furthermore, the control unit 181 may store the selected output signals 145A corresponding to all of the adjustment amounts, and determine an adjustment amount that is the closest to the reference voltage 144A, as the adjustment value 158 for use in the normal operation mode. Furthermore, the control unit 181 may calculate a difference between the voltage of the selected output signal 145A and the reference voltage 144A, and determines an adjustment amount corresponding to the difference, as the adjustment value 158 for use in the normal operation mode.

Although the input offset voltage is adjusted for each of the columns, the source driver 113C may include more than two comparing and determining units 180, and simultaneously adjust the input offset voltages of more than two columns.

### Embodiment 5

Embodiment 4 describes the case where the source driver 113C includes the operational amplifier circuits 160 described in Embodiment 1. Embodiment 5 will describe a source driver 113D including the operational amplifier circuits 160A described in Embodiment 2, and having a function of adjusting an input offset voltage.

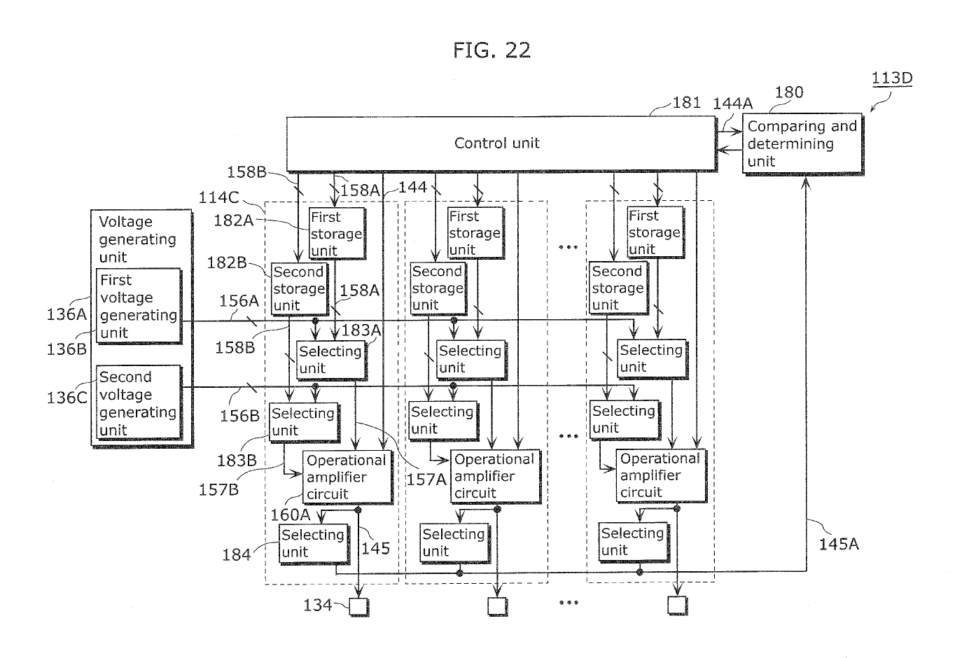

FIG. 22 is a block diagram illustrating a structure of the source driver 113D according to Embodiment 5.

The source driver 113D in FIG. 22 includes a voltage generating unit 136A, N driver circuits 114C, a comparing and determining unit 180, and a control unit 181.

Furthermore, each of the driver circuits 114C includes the operational amplifier circuit 160A, a first storage unit 182A, a second storage unit 182B, and selecting units 183A, 183B, and 184.

Here, the operational amplifier circuits 160A and the voltage generating unit 136A have the same structures as those according to Embodiment 2.

Each of the first storage units 182A stores an adjustment value 158A of an input offset voltage of the operational amplifier circuit 160A in a corresponding column.

Each of the selecting units 183A selects two of voltage signals 156A indicated by the adjustment value 158A stored in the first storage unit 182A, and outputs the selected two voltage signals 156A as a correction voltage signal 157A.

Each of the second storage units 182B stores an adjustment value 158B of an input offset voltage of the operational amplifier circuit 160A in a corresponding column.

Each of the selecting units 183B selects two of voltage signals 156B indicated by the adjustment value 158B stored in the second storage unit 182B, and outputs the selected two voltage signals 156B as a correction voltage signal 157B.

Operations of the source driver 113D will be hereinafter described.

First, the operations of the source driver 113D in the normal operation mode will be described.

In the normal operation mode, a latch address control circuit 130, a latch circuit 131, a level shift circuit 132, and a DA converter circuit 133 sequentially process an image signal 140 corresponding to display data to generate input signals 144 corresponding to the display data.

Furthermore, each of the selecting units 183A selects two of the voltage signals 156A indicated by the adjustment value 158A stored in the first storage unit 182A, and outputs the selected two voltage signals 156A as the correction voltage signal 157A. Furthermore, each of the selecting units 183B selects two of the voltage signals 156B indicated by the adjustment value 158B stored in the second storage unit 182B, and outputs the selected two voltage signals 156B as the correction voltage signal 157B.

Thereby, each of the operational amplifier circuits 160A generates the output signal 145 by driving the input signal 144 in a state where the input offset voltage is adjusted, and outputs the generated output signal 145 to the output terminal 134.

Thereby, an image corresponding to the image signal 140 is displayed on a display unit 111.

Next, the operations of the source driver 113D in the adjustment mode will be described.

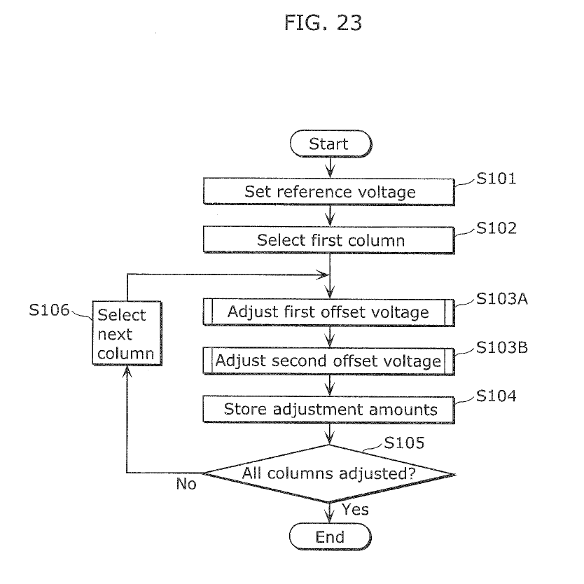

FIG. 23 is a flowchart of the operations of the source driver 113D in the adjustment mode.

As illustrated in FIG. 23, first, the control unit 181 sets the reference voltage 144A (S101). The reference voltage 144A is provided to both the operational amplifier circuits 160A and the comparing and determining unit 180, as the input signal 144. Thereby, each of the operational amplifier circuits 160A outputs the output signal 145 obtained by driving the reference voltage 144A with an adjustment amount of the input offset voltages corresponding to the adjustment value 158A and the adjustment value 158B stored in the present first storage unit 182A and the present second storage unit 182B, respectively.

Next, the control unit 181 controls the selecting units 184 to select the output signal 145 of the operational amplifier circuit 160 in the first column (S102).

Next, the source driver 113D adjusts the first input offset voltage corresponding to the adjustment value 158B (S103A). More specifically, the control unit 181 controls the selecting units 183B to sequentially select the voltage signals 156B. Furthermore, the control unit 181 determines one of the voltage signals 156B indicating that the input offset voltage of a corresponding one of the operational amplifier circuits 160A is in a predetermined range, using a result of the comparison by the comparing and determining unit 180 for each of the voltage signals 156 selected by the selecting unit 183B.

Next, the source driver 113D adjusts the second input offset voltage corresponding to the adjustment value 158A (S103B). More specifically, the control unit 181 controls the selecting units 183A to sequentially select the voltage signals 156A. Furthermore, the control unit 181 determines one of the voltage signals 156A indicating that the input offset voltage of a corresponding one of the operational amplifier circuits 160A is in a predetermined range, using a result of the comparison by the comparing and determining unit 180 for each of the voltage signals 156A selected by the selecting unit 183A.

The details of the processes of adjusting an input offset voltage by the source driver 113D are the same as those according to Embodiment 4.

Then, the control unit 181 stores, in each of the first storage units 182A and each of the second storage units 182B, adjustment amounts adjusted at Steps 5103A and 5103B, as the adjustment values 158A and 158B for use in the normal operation mode (S104).

When all the columns are not yet adjusted (No at S105), next, the control unit 181 controls the selecting units 184 to select the output signal 145 of the operational amplifier circuit 160A in the next column (S106), and the processes after Step 5103A are performed.

When all the columns have been adjusted (Yes at S105), the control unit 181 ends the adjustment mode and changes to the normal operation mode.

As described above, the source driver 113D according to Embodiment 5 can automatically adjust an input offset voltage of the operational amplifier circuit 160A.

Although the example where the source driver 113D includes the second storage unit 182B that stores the adjustment value 158B, for each of the columns, the structure may be as follows.

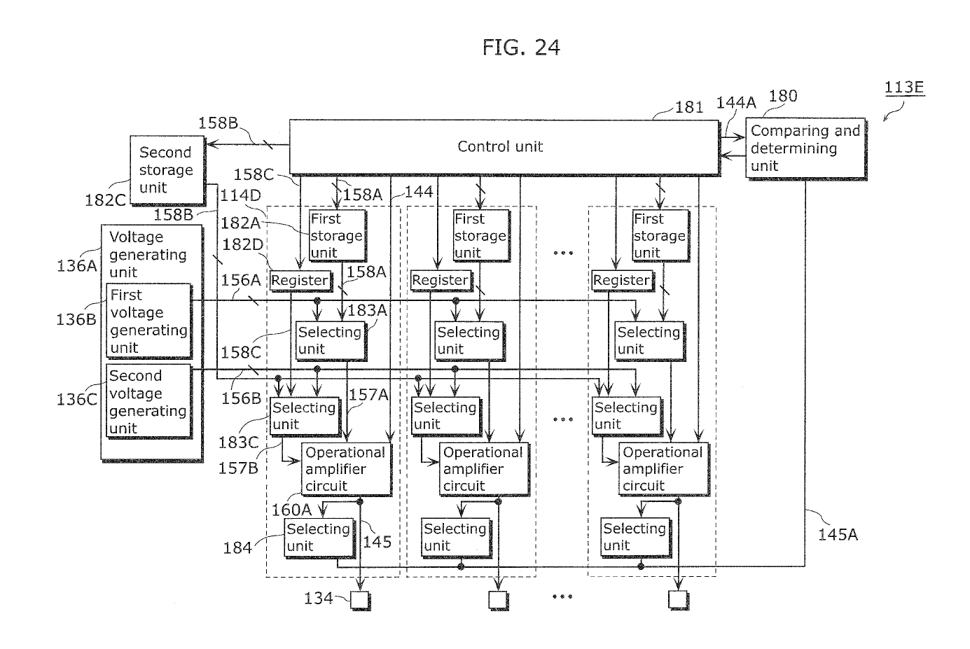

FIG. 24 illustrates a modified example of a structure of the source driver 113D according to Embodiment 5.

A source driver 113E in FIG. 24 includes, instead of the second storage unit 182B provided for each of the columns, a second storage unit 182C for all the columns, and a register 182D provided for each of the columns. Furthermore, each of selecting units 183C that is included in the driver circuit 114D differs in structure from the selecting unit 183B.

The second storage unit 182C stores an adjustment value 158B for one column.

Each of the registers 182D holds valid information 158C indicating whether or not the adjustment value 158B is valid.

Each of the selecting units 183C selects two of voltage signals 156B indicated by the adjustment value 158B stored in the second storage unit 182C when the valid information 158C indicates that the adjustment value 158B is valid, and outputs the selected two voltage signals 156B as a correction voltage signal 157B. Furthermore, each of the selecting units 183C selects predetermined two of the voltage signals 156B when the valid information 158C indicates that the adjustment value 158B is invalid, and outputs the selected two voltage signals 156B as the correction voltage signal 157B. For example, each of the selecting units 183C sets the correction voltage signals 157c and 157d included in the correction voltage signal 157B to the same voltage value. in other words, the second correction current supply unit 177B does not adjust an input offset voltage.

Furthermore, the control unit 181 updates the second storage unit 182C and the registers 182D at Step S104 in FIG. 23.

Here, as described in Embodiment 2, the input offset voltages of the operational amplifier circuits 160A include an input offset voltage of the order of several millivolts caused by manufacturing variation and temperature change in the differential transistors M1 and M2, and an input offset voltage of the order of several tens of millivolts caused by mask misalignment in manufacturing. The occurrence frequency of the input offset voltage of the order of several millivolts is fewer than that of the input offset voltage of the order of several tens of millivolts.

Thus, the capacity of the storage unit to store information for determining an adjustment amount in the second correction current supply unit 177B can be reduced by storing the adjustment value 158B for adjusting the input offset voltage of the order of several tens of millivolts, in the second storage unit 182 used for all the columns in common.

For example, the adjustment value 158B is data of several bits, and the valid information 158C is data of one bit. The second storage unit 182C may store the adjustment values 158B. In this case, the number of bits of the valid information 158C has only to be increased according to the number of the adjustment values 158B to be stored in the second storage unit 182C.

Although the control unit 181 performs the first offset voltage adjustment process (S103A) and the second offset voltage adjustment process (S103B) for each of the columns, it may perform, for all of the columns, the first offset voltage adjustment process (S103A), and then the second offset voltage adjustment process (S103B).

### Embodiment 6

Embodiment 6 will describe a source driver 113F including the operational amplifier circuits 160B described in Embodiment 3, and having a function of adjusting an input offset voltage.

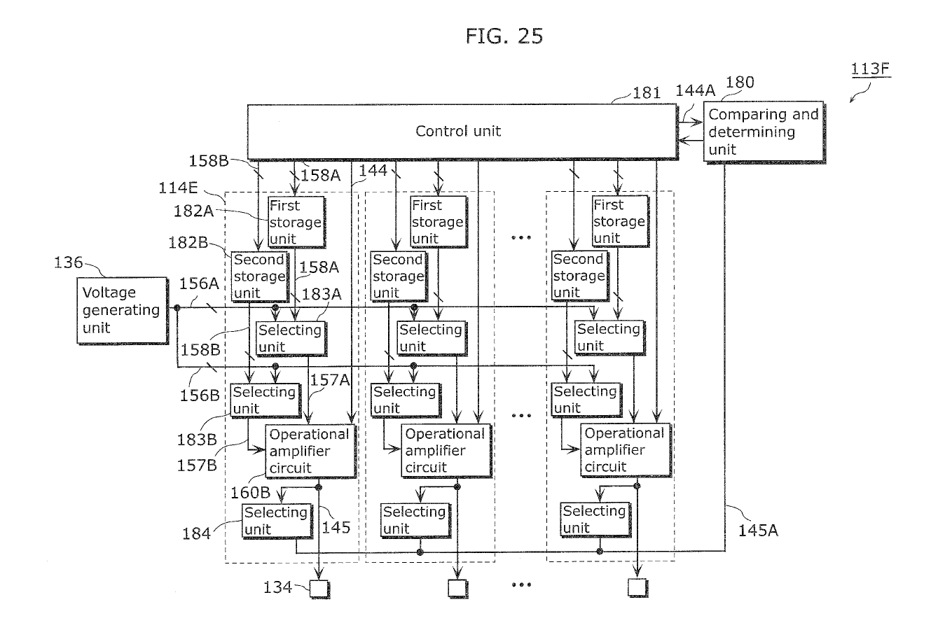

FIG. 25 is a block diagram illustrating a structure of the source driver 113F according to Embodiment 6.

The source driver 113F in FIG. 25 includes a voltage generating unit 136, N driver circuits 114E, a comparing and determining unit 180, and a control unit 181.

Furthermore, each of the driver circuits 114E includes the operational amplifier circuit 160B, a first storage unit 182A, a second storage unit 182B, and selecting units 183A, 183B, and 184.

Here, each of the operational amplifier circuits 160B has the same structure as that according to Embodiment 3.

The voltage generating unit 136 generates voltage signals 156 having different voltages.

Each of the first storage units 182A stores an adjustment value 158A of an input offset voltage of the operational amplifier circuit 160B in a corresponding column.

Each of the selecting units 183A selects two of the voltage signals 156 indicated by the adjustment value 158A stored in the first storage unit 182A, and outputs the selected two voltage signals 156 as a correction voltage signal 157A.

Each of the second storage units 182B stores an adjustment value 158B of an input offset voltage of the operational amplifier circuit 160B in a corresponding column.

Each of the selecting units 183B selects two of the voltage signals 156 indicated by the adjustment value 158B stored in the second storage unit 182B, and outputs the selected two voltage signals 156 as a correction voltage signal 157B.

Here, the voltage generating unit 136 may generate voltage signals 156A and voltage signals 156B, each of the selecting units 183A may select two of the voltage signals 156A, and each of the selecting units 183B may select two of the voltage signals 156B.

Operations of the source driver 113F will be hereinafter described.

First, the operations of the source driver 113F in the normal operation mode will be described.

In the normal operation mode, a latch address control circuit 130, a latch circuit 131, a level shift circuit 132, and a DA converter circuit 133 sequentially process an image signal 140 corresponding to display data to generate input signals 144 corresponding to the display data.

Each of the selecting units 183A selects two of the voltage signals 156 indicated by the adjustment value 158A stored in the first storage unit 182A, and outputs the selected two voltage signals 156 as the correction voltage signal 157A. Furthermore, each of the selecting units 183B selects two of the voltage signals 156 indicated by the adjustment value 158B stored in the second storage unit 182B, and outputs the selected two voltage signals 156 as the correction voltage signal 157B.

Thereby, each of the operational amplifier circuits 160B generates the output signal 145 by driving the input signal 144 in a state where the input offset voltage is adjusted, and outputs the generated output signal 145 to the output terminal 134.

Thereby, an image corresponding to the image signal 140 is displayed on a display unit 111.

Next, the operations of the source driver 113F in the adjustment mode will be described.

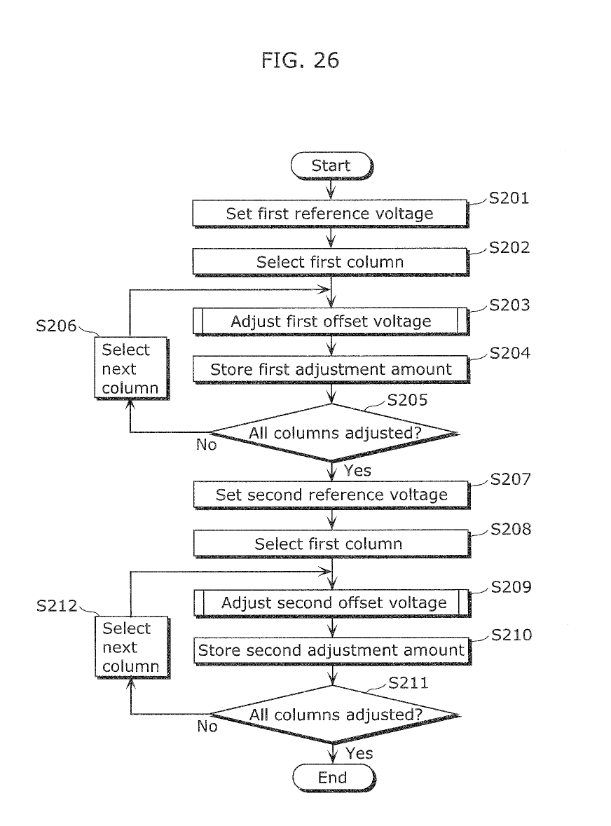

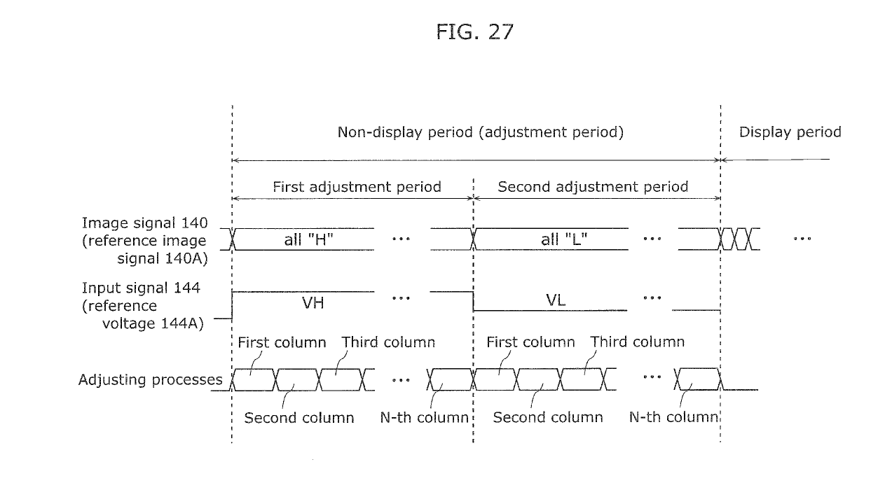

FIG. 26 is a flowchart of the operations of the source driver 113F in the adjustment mode. FIG. 27 is a timing chart illustrating an example of the operations of the source driver 113F in the adjustment mode.

Furthermore, examples of the adjustment mode include a first adjustment mode for adjusting the adjustment value 158A (first adjustment period), and a second adjustment mode for adjusting the adjustment value 158B (second adjustment period).

First, processes for the first adjustment mode are performed according to Steps S201 to 206 in FIG. 26.

Here, the control unit 181 sets the first reference voltage VH as the reference voltage 144A (S201).

More specifically, the control unit 181 provides the latch address control circuit 130 with the reference image signal 140A that is a digital signal corresponding to the first reference voltage VH. The latch address control circuit 130, the latch circuit 131, the level shift circuit 132, and the DA converter circuit 133 sequentially process the reference image signal 140A to generate the first reference voltage VH. The first reference voltage VH is provided to both the operational amplifier circuits 160B and the comparing and determining unit 180, as the input signal 144.

Furthermore, the first reference voltage VH is in a voltage range in which the second differential pair (the differential transistors MP11 and MP12) does not operate and the first differential pair (differential transistors M11 and M12) that are included in each of the R-R operational amplifier circuits 160B operates. More specifically, the first reference voltage VH is a voltage equal to or higher than a voltage value obtained by subtracting, from the supply voltage VDD, the threshold voltage of the differential transistors MP11 and MP12.

For example, as illustrated in FIG. 27, the control unit 181 outputs a signal whose bits are all high, as the reference image signal 140A. Thereby, for example, the DA converter circuit 133 outputs the supply voltage VDD of −0.5 V as the first reference voltage VH.

Furthermore, each of the operational amplifier circuits 160B outputs the output signal 145 obtained by driving the first reference voltage VH with an adjustment amount of the input offset voltage corresponding to the adjustment value 158A and the adjustment value 158B stored in the present first storage unit 182A and the present second storage unit 182B, respectively.

Next, the control unit 181 controls the selecting units 184 to select the output signal 145 of the operational amplifier circuit 160B in the first column (S202).

Next, the source driver 113F adjusts the first input offset voltage corresponding to the adjustment value 158A (S203). More specifically, the control unit 181 controls the selecting units 183A to sequentially select the voltage signals 156. Furthermore, the control unit 181 determines one of the voltage signals 156 indicating that the input offset voltage of a corresponding one of the operational amplifier circuits 160B is in a predetermined range, using a result of the comparison by the comparing and determining unit 180 for each of the voltage signals 156 selected by the selecting unit 183A.

The details of the process of adjusting an input offset voltage by the source driver 113F are the same as those according to Embodiment 4.

Here, since the input signal 144 is the first reference voltage VH, the second differential pair (the differential transistors MP11 and MP12) does not operate. Thus, the input offset voltage of the first differential pair can be adjusted at Step S203 only in consideration of the influence thereof.

Next, the control unit 181 stores, in each of the first storage units 182A, the first adjustment amount adjusted at Step S203 as the adjustment value 158A for use in the normal operation mode (S204).

When all the columns are not yet adjusted (No at S205), next, the control unit 181 controls the selecting units 184 to select the output signal 145 of the operational amplifier circuit 160B in the next column (S206), and the processes after Step S203 are performed.

When all the columns have been adjusted (Yes at S205), processes for the second adjustment mode are performed according to Steps S207 to S212 in FIG. 26.

Here, the control unit 181 sets a second reference voltage VL as the reference voltage 144A (S207).

More specifically, the control unit 181 provides the latch address control circuit 130 with the reference image signal 140A that is a digital signal corresponding to the second reference voltage VL. The latch address control circuit 130, the latch circuit 131, the level shift circuit 132, and the DA converter circuit 133 sequentially process the reference image signal 140A to generate the second reference voltage VL. The second reference voltage VL is provided to both the operational amplifier circuits 160B and the comparing and determining unit 180, as the input signal 144.

Furthermore, the second reference voltage VL is in a voltage range in which the first differential pair (the differential transistors M11 and M12) does not operate and the second differential pair (the differential transistors MP11 and MP12) operates. The first differential pair and the second differential pair are included in each of the R-R operational amplifier circuits 160B. More specifically, the second reference voltage VL is a voltage equal to or lower than threshold voltage of the differential transistors M11 and M12.

For example, as illustrated in FIG. 27, the control unit 181 outputs a signal whose bits are all low, as the reference image signal 140A. Thereby, for example, the DA converter circuit 133 outputs 0.5 V as the second reference voltage VL.

Furthermore, each of the operational amplifier circuits 160B outputs the output signal 145 obtained by driving the second reference voltage VL with an adjustment amount of the input offset voltage corresponding to the adjustment value 158A and the adjustment value 158B stored in the present first storage unit 182A and the present second storage unit 182B, respectively.

Next, the control unit 181 controls the selecting units 184 to select the output signal 145 of the operational amplifier circuit 160B in the first column (S208). More specifically, the control unit 181 controls the selecting units 183 to sequentially select the voltage signals 156. Furthermore, the control unit 181 determines one of the voltage signals 156 indicating that the input offset voltage of a corresponding one of the operational amplifier circuits 160B is in a predetermined range, using a result of the comparison by the comparing and determining unit 180 for each of the voltage signals 156 selected by the selecting unit 183B.

Next, the source driver 113F adjusts the second input offset voltage corresponding to the adjustment value 158B (S209).

The details of the processes of adjusting an input offset voltage by the source driver 113F are the same as those according to Embodiment 4.

Here, since the input signal 144 is the second reference voltage VL, the first differential pair (the differential transistors M11 and M12) does not operate. Thus, the input offset voltage of the second differential pair can be adjusted at Step S209 only in consideration of the influence thereof.

Next, the control unit 181 stores, in each of the second storage units 182B, the second adjustment amount adjusted at Step S209 as the adjustment value 158B for use in the normal operation mode (S210).

When all the columns are not yet adjusted (No at S211), next, the control unit 181 controls the selecting units 184 to select the output signal 145 of the operational amplifier circuit 160B in the next column (S212), and the processes after Step S209 are performed.

When all the columns have been adjusted (Yes at S211), the control unit 181 ends the adjustment mode and changes to the normal operation mode.

As described above, the source driver 113F according to Embodiment 6 adjusts, as the reference voltage 144A, the input offset voltage of the first differential pair, using the first reference voltage VH with which only the first differential pair operates. Furthermore, the source driver 113F adjusts, as the reference voltage 144A, the input offset voltage of the second differential pair, using the second reference voltage VL with which only the second differential pair operates. Thereby, the source driver 113F can adjust the input offset voltage for each of the first differential pair and the second differential pair, without any influence of the other of the first differential pair and the second differential pair. Thereby, the source driver 113F can automatically adjust an input offset voltage of the R-R operational amplifier circuit 160B with high precision.

Furthermore, as illustrated in FIG. 27, the source driver 113F adjusts the input offset voltage during a non-display period during which no image is displayed on the display unit 111. In other words, the control unit 181 sets the source driver 113F to the adjustment mode during the non-display period. The non-display period includes, for example, timing when a display device 100 is turned on.

Furthermore, the source drivers 113D and 113E according to Embodiments 4 and 5 may adjust input offset voltages during the non-display period.

Although the second adjustment period for adjusting the adjustment value 158B of the second differential pair follows the first adjustment period for adjusting the adjustment value 158A of the first differential pair in the examples of FIGS. 26 and 27, the source driver 113F may adjust the adjustment value 158A after adjusting the adjustment value 158B.

Furthermore, although the source driver 113F adjusts, for the operational amplifier circuits 160B in all the columns, the adjustment values 158A and then the adjustment values 158B, it may adjust the adjustment values 158A and 158B for each of the columns and may change a column to be adjusted.

### Embodiment 7

Embodiment 7 describes a modified example of the source driver 113F according to Embodiment 6.

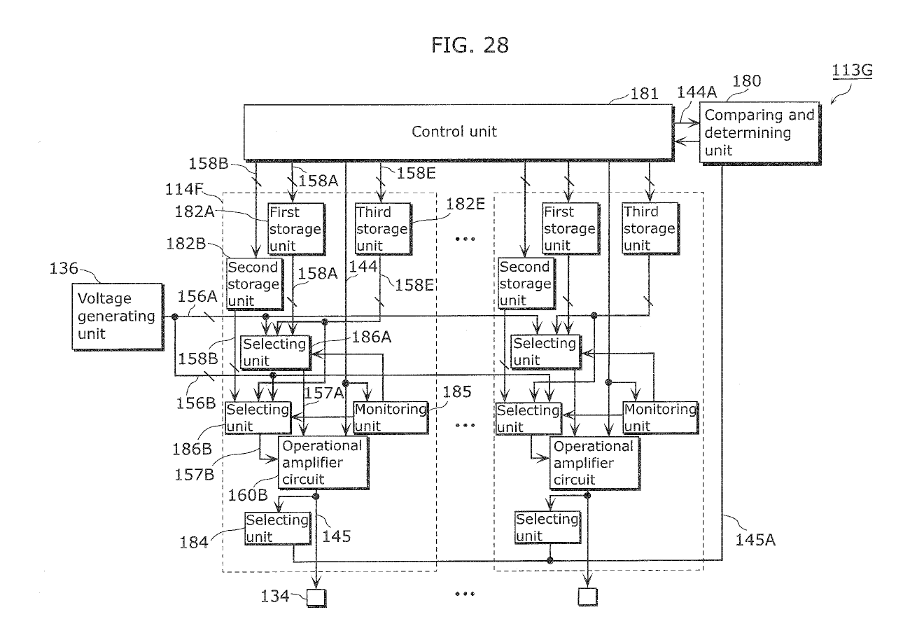

FIG. 28 is a block diagram illustrating a structure of a source driver 113G according to Embodiment 7.

The source driver 113G in FIG. 28 includes a voltage generating unit 136, N driver circuits 114F, a comparing and determining unit 180, and a control unit 181.

Each of the driver circuits 114F included in the source driver 113G differs in structure from the source driver 114E according to Embodiment 6.

More specifically, each of the driver circuits 114F further includes a third storage unit 182E and a monitoring unit 185, in addition to the constituent elements of the source driver 114E. Furthermore, each of the driver circuits 114F includes selecting units 186A and 186B instead of the selecting units 183A and 183B.

Each of the third storage units 182E stores an adjustment value 158E of an input offset voltage of the operational amplifier circuit 160B in a corresponding column. The examples of the adjustment value 158E include an adjustment value for specifying two of voltage signals 156 corresponding to the correction voltage signal 157A, and an adjustment value for specifying two of the voltage signals 156 corresponding to the correction voltage signal 157B.

Each of the monitoring units 185 monitors a voltage value of the input signal 144. More specifically, each of the monitoring units 185 determines whether or not the input signal 144 is in a second voltage range.

Each of the selecting units 186A selects two of the voltage signals 156 indicated by the adjustment value 158A stored in the first storage unit 182A when the monitoring unit 185 determines that the input signal 144 is out of the second voltage range, and outputs the selected two voltage signals 156 as the correction voltage signal 157A.

Furthermore, each of the selecting units 186A selects two of the voltage signals 156 indicated by the adjustment value 158E stored in the third storage unit 182E when the monitoring unit 185 determines that the input signal 144 is in the second voltage range, and outputs the selected two voltage signals 156 as the correction voltage signal 157A.

Each of the selecting units 186B selects two of the voltage signals 156 indicated by the adjustment value 158B stored in the second storage unit 182B when the monitoring unit 185 determines that the input signal 144 is out of the second voltage range, and outputs the selected two voltage signals 156 as a correction voltage signal 157B.

Furthermore, each of the selecting units 186B selects two of the voltage signals 156 indicated by the adjustment value 158E stored in the third storage unit 182E when the monitoring unit 185 determines that the input signal 144 is out of the second voltage range, and outputs the selected two voltage signals 156 as the correction voltage signal 157B.

Operations of the source driver 113G will be hereinafter described.

First, the operations of the source driver 113G in the normal operation mode will be described.

In the normal operation mode, a latch address control circuit 130, a latch circuit 131, a level shift circuit 132, and a DA converter circuit 133 sequentially process an image signal 140 corresponding to display data to generate input signals 144 corresponding to the display data.

Each of the monitoring units 185 determines whether or not the input signal 144 is in the second voltage range.

Each of the selecting units 186A selects two of the voltage signals 156 indicated by the adjustment value 158A stored in the first storage unit 182A when the monitoring unit 185 determines that the input signal 144 is out of the second voltage range, and outputs the selected two voltage signals 156 as the correction voltage signal 157A. Furthermore, each of the selecting units 186B outputs, as the correction voltage signal 157B, two of the voltage signals 156 indicated by the adjustment value 158B stored in the second storage unit 182B.

On the other hand, each of the selecting units 186A outputs, as the correction voltage signal 157A, two of the voltage signals 156 indicated by the adjustment value 158E stored in the third storage unit 182E when the monitoring unit 185 determines that the input signal 144 is in the second voltage range. Furthermore, each of the selecting units 186B outputs, as the correction voltage signal 157B, two of the voltage signals 156 indicated by the adjustment value 158E stored in the third storage unit 182E.

Thereby, each of the operational amplifier circuits 160B generates the output signal 145 by driving the input signal 144 in a state where the input offset voltage is adjusted, and outputs the generated output signal 145 to the output terminal 134.

Thereby, an image corresponding to the image signal 140 is displayed on a display unit 111.

Next, the operations of the source driver 113G in the adjustment mode will be described.

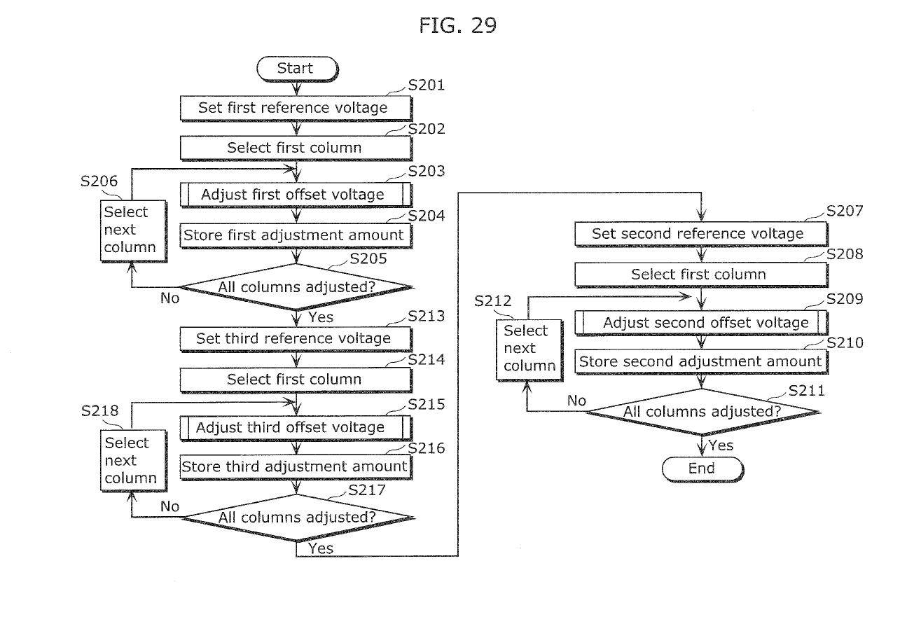

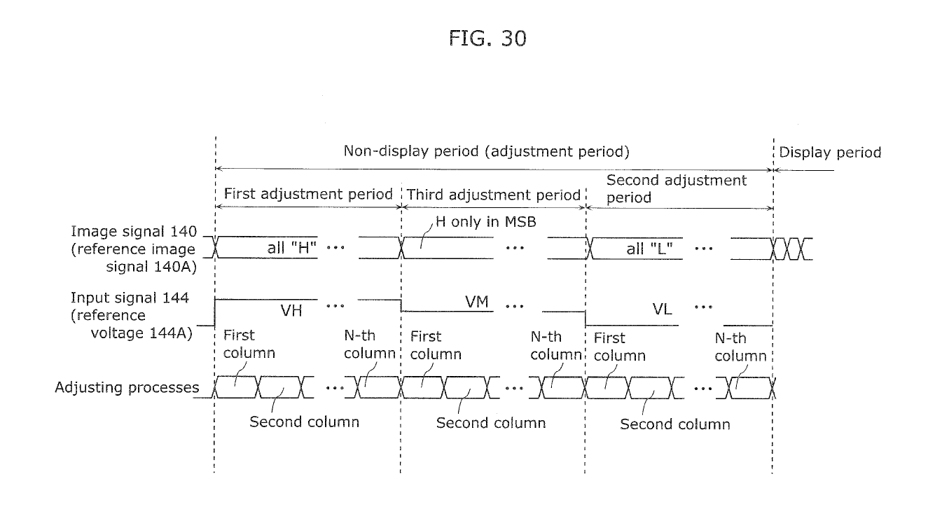

FIG. 29 is a flowchart of the operations of the source driver 113G in the adjustment mode. Furthermore, FIG. 30 is a timing chart illustrating an example of the operations of the source driver 113G in the adjustment mode.

Furthermore, examples of the adjustment mode include a first adjustment mode for adjusting the adjustment value 158A (first adjustment period), a third adjustment mode for adjusting the adjustment value 158E (third adjustment period), and a second adjustment mode for adjusting the adjustment value 158B (second adjustment period).

The description of the processes at Steps S201 to S206 (the first adjustment mode) and the processes at Steps S207 to S212 (the second adjustment mode) that are the same as those according to Embodiment 6 will be omitted.

When all the columns have been adjusted at Step S205 (Yes at S205), processes for the third adjustment mode are performed according to Steps S213 to S218 in FIG. 29.

First, the control unit 181 sets a third reference voltage VM as the reference voltage 144A (S213).

More specifically, the control unit 181 provides the latch address control circuit 130 with the reference image signal 140A that is a digital signal corresponding to the third reference voltage VM. The latch address control circuit 130, the latch circuit 131, the level shift circuit 132, and the DA converter circuit 133 sequentially process the reference image signal 140A to generate the third reference voltage VM. The third reference voltage VM is provided to both the operational amplifier circuits 160B and the comparing and determining unit 180, as the input signal 144.

Furthermore, the third reference voltage VM is in the second voltage range in which both the first differential pair (differential transistors M11 and M12) and the second differential pair (differential transistors MP11 and MP12) that are included in each of the R-R operational amplifier circuits 160B operate. More specifically, the third reference voltage VM is a voltage equal to or higher than the threshold voltage of the differential transistors M11 and M12 and equal to or lower than a voltage value obtained by subtracting, from the supply voltage VDD, the threshold voltage of the differential transistors MP11 and MP12.

For example, as illustrated in FIG. 29, the control unit 181 outputs a signal in which only the most significant bit (MSB) is high, as the reference image signal 140A. Thereby, for example, the DA converter circuit 133 outputs VDD/2 as the third reference voltage VM.

Furthermore, each of the operational amplifier circuits 160B outputs the output signal 145 obtained by driving the third reference voltage VM with an adjustment amount of the input offset voltage corresponding to the adjustment value 158E stored in the present third storage unit 182E.

Next, the control unit 181 controls the selecting units 184 to select the output signal 145 of the operational amplifier circuit 160B in the first column (S214).

Next, the source driver 113G adjusts the third input offset voltage corresponding to the adjustment value 158E (S215). More specifically, the control unit 181 controls the selecting units 186A and 186B to sequentially select the voltage signals 156. Furthermore, the control unit 181 determines one of the voltage signals 156 indicating that the input offset voltage of a corresponding one of the operational amplifier circuits 160B is in a predetermined range, using a result of the comparison by the comparing and determining unit 180 for each of the voltage signals 156 selected by the selecting units 186A and 186B.

The details of the process of adjusting an input offset voltage by the source driver 113G are the same as that, for example, according to Embodiment 4.

Here, since the input signal 144 is the third reference voltage VM, both the first and second differential pairs operate. Thus, the input offset voltage when both the first and second differential pairs operate can be adjusted at Step S215.

Next, the control unit 181 stores, in each of the third storage units 182E, the adjustment amount adjusted at Step S215 as the adjustment value 158E for use in the normal operation mode (S216).

When all the columns are not yet adjusted (No at S217), next, the control unit 181 controls the selecting units 184 to select the output signal 145 of the operational amplifier circuit 160B in the next column (S218), and the processes after Step S215 are performed.

As described above, the source driver 113G according to Embodiment 7 adjusts the input offset voltage as the reference voltage 144A for each of cases where only the first differential pair operates, where only the second differential pair operates, and where both the first and second differential pairs operate, using the first reference voltage VH in which only the first differential pair operates, the second reference voltage VL in which only the second differential pair operates, and the third reference voltage VM in which both the first and second differential pairs operate, respectively. Thereby, the source driver 113G can automatically adjust an input offset voltage of the R-R operational amplifier circuit 160B with high precision.

Furthermore, as illustrated in FIG. 30, the source driver 113G adjusts the input offset voltage during a non-display period during which no image is displayed on the display unit 111. The non-display period includes, for example, timing when a display device 100 is turned on.

Although the source driver 113G adjusts adjustment values in order of the adjustment values 158A, 158E, and 158B in the examples of FIGS. 29 and 30, the order thereof may be any order.

Furthermore, although the source driver 113G adjusts, for the operational amplifier circuits 160B in all the columns, the adjustment value 158A, then the adjustment value 158E, and lastly the adjustment value 158B, it may adjust the adjustment values 158A, 158E, and 158B for each of the columns and may change a column to be adjusted.

Furthermore, although each of Embodiments 4 to 7 exemplifies a signal driver (source driver) including operational amplifier circuits, the present invention may be applicable to a signal driver that determines an input offset voltage for one operational amplifier circuit and adjusts the input offset voltage.

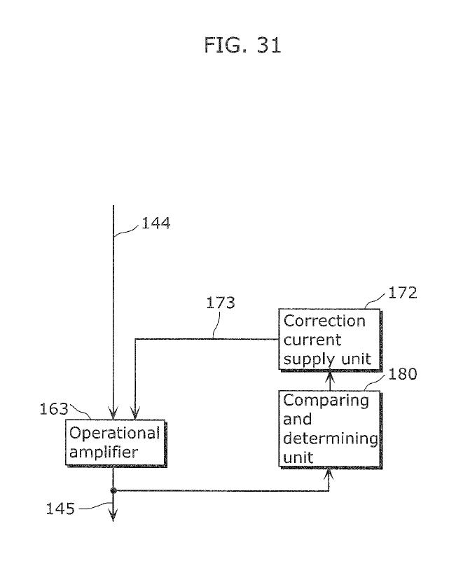

FIG. 31 is a block diagram illustrating a structure of a signal driver in such a case. The signal driver in FIG. 31 includes an operational amplifier 163, a correction current supply unit 172, and a comparing and determining unit 180.

Furthermore, the present invention may be implemented as a method of adjusting an input offset voltage of an operational amplifier circuit.

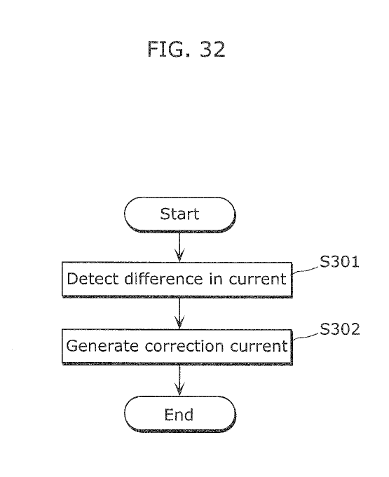

FIG. 32 is a flowchart of the method of adjusting an input offset voltage of an operational amplifier circuit according to the present invention.

As illustrated in FIG. 32, the comparing and determining unit 180 detects a voltage difference between the input signal 144 and the output signal 145 to detect a difference between a current that flows through the first differential transistor M1 and a current that flows through the second differential transistor M2 (S301).

Next, the correction current supply unit 172 generates a correction current 173 for correcting the difference in current detected by the comparing and determining unit 180, and supplies the operational amplifier 163 with the generated correction current 173 (S302).

### Embodiment 8

Embodiment 8 describes a modified example of Embodiment 1.

An operational amplifier circuit 160H according to Embodiment 8 in the present invention does not supply any correction current to a differential amplifier 170 during a predetermined period immediately after an input signal 144 is changed. Thereby, the operational amplifier circuit 160H can improve the operating speed.

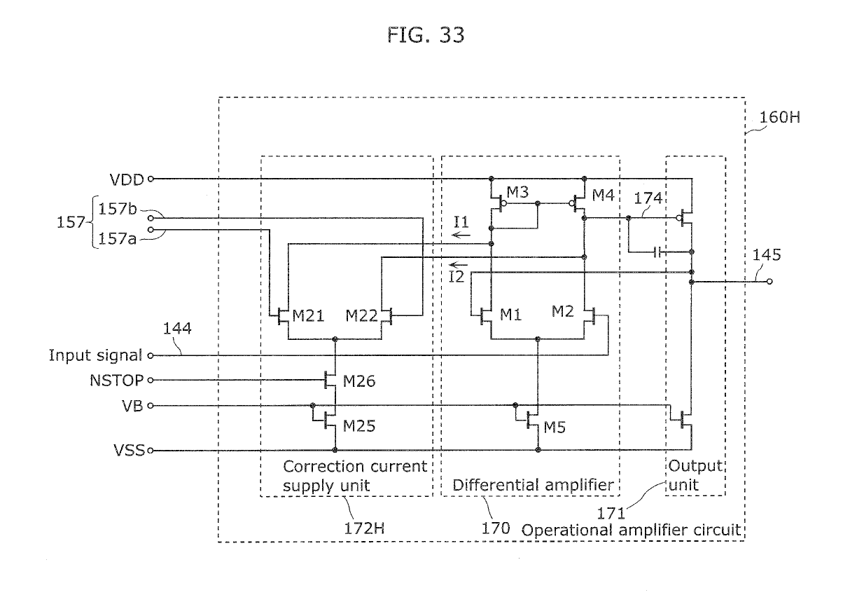

FIG. 33 illustrates a structure of the operational amplifier circuit 160H according to Embodiment 8.

In FIG. 33, a correction current supply unit 172H included in the operational amplifier circuit 160H differs in structure from the correction current supply unit 172 included in the operational amplifier circuit 160 in FIG. 7. The same constituent elements as those in FIG. 7 are denoted by the same reference numerals, in FIG. 33.

The correction current supply unit 172H further includes a cut-off transistor M26, in addition to the constituent elements of the correction current supply unit 172.

The cut-off transistor M26 has a gate terminal to which a stop control signal NSTOP is applied, a source terminal connected to a drain terminal of a current source transistor M25, and a drain terminal connected to source terminals of correction transistors M21 and M22.

With the structure, the correction current supply unit 172H supplies the differential amplifier 170 with a correction current when the stop control signal NSTOP is in a high level, and does not supply the differential amplifier 170 with the correction current when the stop control signal NSTOP is in a low level.

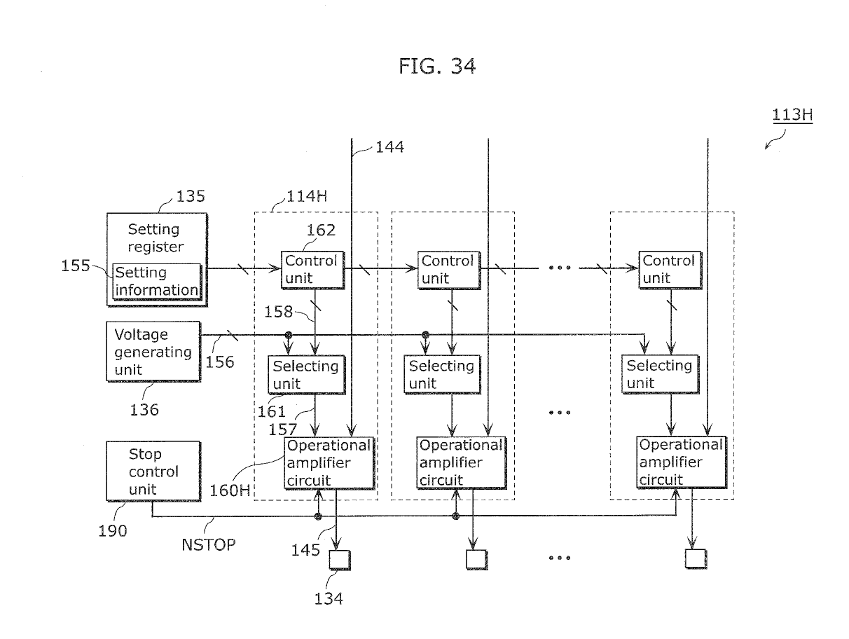

FIG. 34 is a block diagram illustrating a structure of driver circuits 114H and the peripheral circuits according to Embodiment 8. As illustrated in FIG. 34, the source driver 113H according to Embodiment 8 further includes a stop control unit 190 that generates the stop control signal NSTOP.

The stop control unit 190 stops supplying the correction current from the correction current supply unit 172H to the differential amplifier 170 for a predetermined period from the time when the input signal 144 is changed.

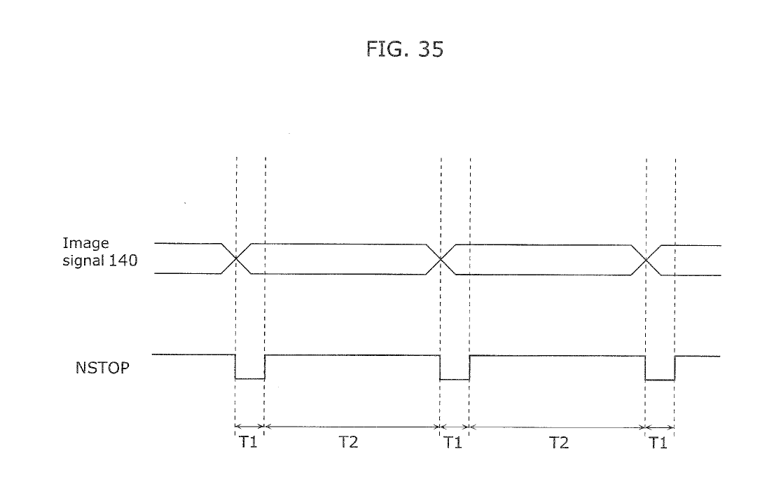

FIG. 35 illustrates an example of the stop control signal NSTOP. As illustrated in FIG. 35, the stop control signal NSTOP is in the low level during a period T1 immediately after the image signal 140 (the input signal 144) is changed.

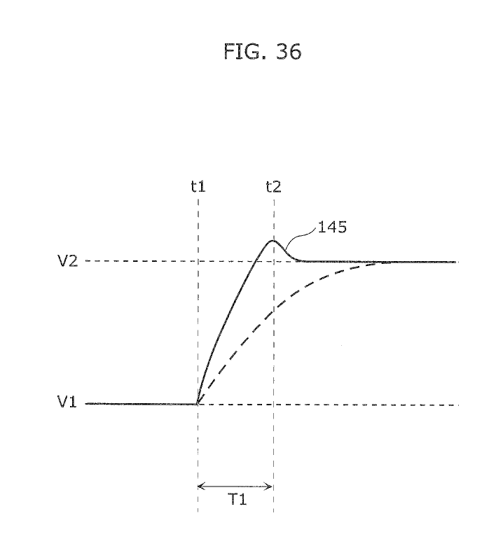

FIG. 36 illustrates the output signal 145 when the input signal 144 changes from a voltage V1 to a voltage V2. The dotted line in FIG. 36 indicates change in the output signal 145 when a correction current is always supplied.

Here, supply of the correction current increases currents that flow through load transistors M3 and M4. As a result, the amplification factor of the differential amplifier 170 decreases. In other words, the time period until when the output signal 145 reaches a predetermined voltage (the same voltage as that of the input signal 144) is prolonged.

On the other hand, during the period T1 immediately after the image signal 140 is changed, the time until when the output signal 145 reaches the voltage V2 can be shortened as illustrated in FIG. 36. Furthermore, with the correction current supplied after the time t2, the output signal 145 is set to a voltage in which the input offset voltage has been adjusted.

As described above, the operational amplifier circuit 160H according to Embodiment 8 can improve the operating speed.

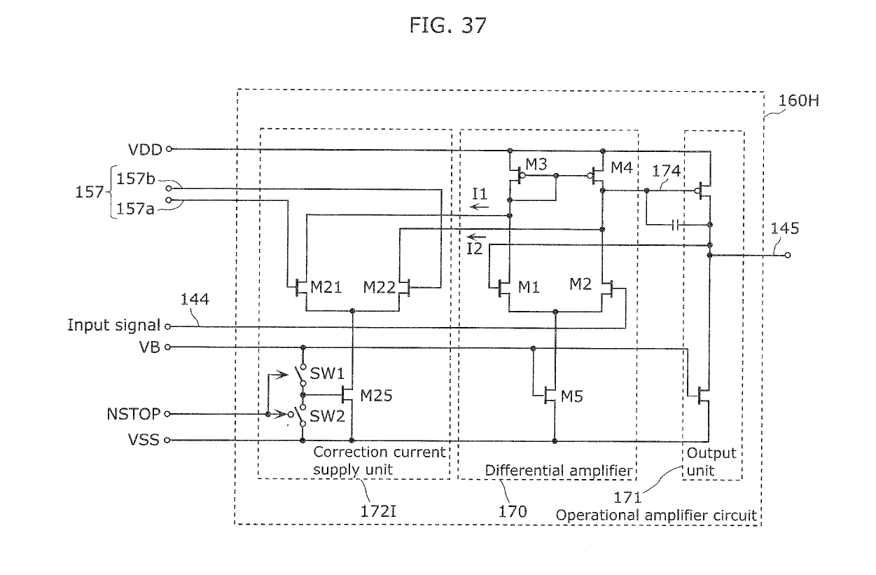

The current source transistor M25 may be turned off during the period T1, instead of providing the cut-off transistor M26. FIG. 37 illustrates a structure of a correction current supply unit 1721 in such a case.

The correction current supply unit 1721 further includes switches SW1 and SW2.

When the stop control signal NSTOP is in the high level, the switch SW1 is turned on, and the switch SW2 is turned off. Since a bias voltage VB is applied to a gate terminal of the current source transistor M25 in this case, the correction current supply unit 1721 supplies a correction current to the differential amplifier 170.

When the stop control signal NSTOP is in the low level, the switch SW1 is turned off, and the switch SW2 is turned on. Since a ground potential VSS is applied to the gate terminal of the current source transistor M25 in this case, the correction current supply unit 1721 does not supply a correction current to the differential amplifier 170.

Here, the switches SW1 and SW2 are, for example, transistors.

The same example of the modification may be applied to the structures in FIGS. 9 and 10.

### Embodiment 9

Embodiment 9 will describe an example in which the modified example in Embodiment 8 is applied to the operational amplifier circuits 160 described in Embodiment 2.

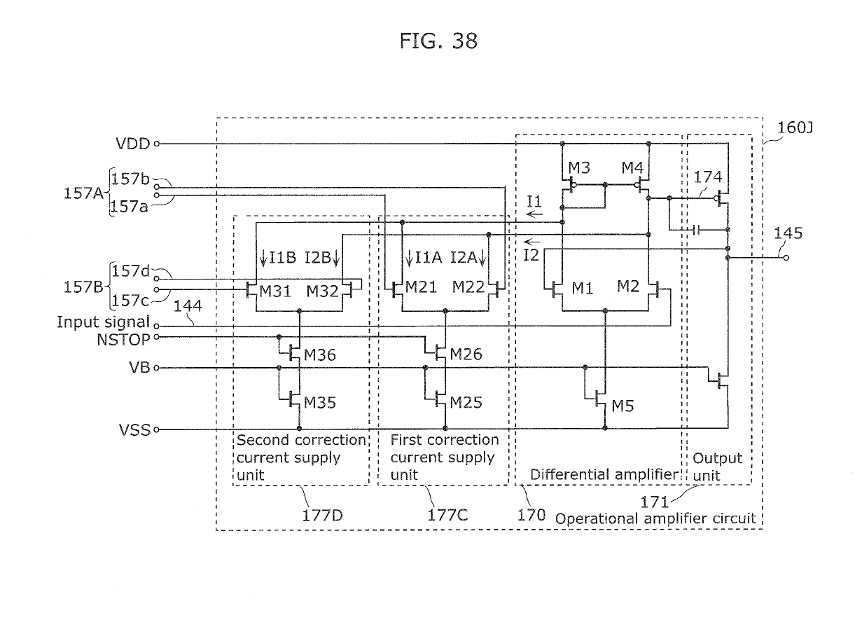

FIG. 38 illustrates a structure of an operational amplifier circuit 1603 according to Embodiment 9.

A first correction current supply unit 177C and a second correction current supply unit 177D included in the operational amplifier circuit 1603 in FIG. 38 differ in structure from the first correction current supply unit 177A and the second correction current supply unit 177B included in the operational amplifier circuit 160A in FIG. 13. The same constituent elements as those in FIG. 13 are denoted by the same reference numerals, in FIG. 38.

The first correction current supply unit 177C further includes a cut-off transistor M26, in addition to the constituent elements of the first correction current supply unit 177A.

The cut-off transistor M26 has a gate terminal to which a stop control signal NSTOP is applied, a source terminal connected to a drain terminal of a current source transistor M25, and a drain terminal connected to source terminals of correction transistors M21 and M22.

The second correction current supply unit 177D further includes a cut-off transistor M36, in addition to the constituent elements of the second correction current supply unit 177B.

The cut-off transistor M36 has a gate terminal to which the stop control signal NSTOP is applied, a source terminal connected to a drain terminal of a current source transistor M35, and a drain terminal connected to source terminals of correction transistors M31 and M32.

With the structure, each of the first correction current supply unit 177C and the second correction current supply unit 177D supplies the differential amplifier 170 with a correction current when the stop control signal NSTOP is in a high level, and does not supply the differential amplifier 170 with the correction current when the stop control signal NSTOP is in a low level.

Furthermore, a stop control unit 190 generates the stop control signal NSTOP in the same manner as Embodiment 8. In other words, the stop control unit 190 stops supplying, for a predetermined period from the time when the input signal 144 is changed, (i) a first correction current from the first correction current supply unit 177C to the differential amplifier 170, and (ii) a second correction current from the second correction current supply unit 177D to the differential amplifier 170.

As described above, the operational amplifier circuit 1603 according to Embodiment 9 can improve the operating speed as the operational amplifier circuit 160H according to Embodiment 8.

### Embodiment 10

Embodiment 10 will describe a modified example of Embodiment 3.

Here, the structure in FIG. 16 according to Embodiment 3 has following problems.

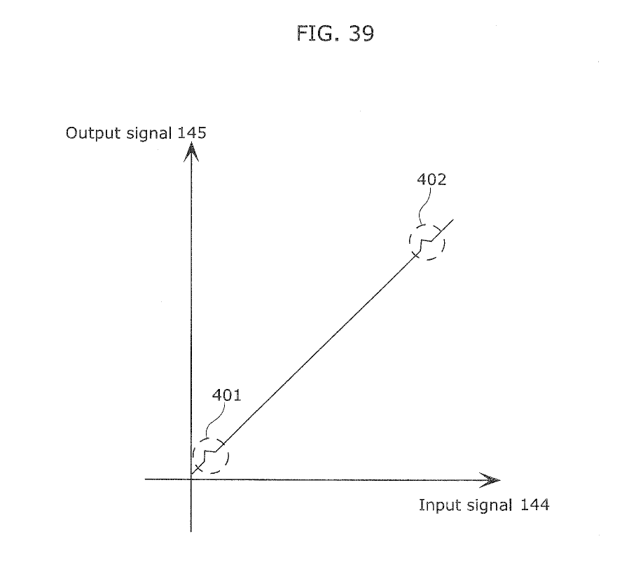

FIG. 39 is a graph illustrating a relationship between the input signal 144 and the output signal 145 in the circuit structure of FIG. 16 to describe the problems.

When the threshold voltage of the cut-off transistor M46 is lower than the threshold voltage of the differential transistors M11 and M12 due to manufacturing variation, there are cases where the cut-off transistor M46 is turned on in a state where the differential transistors M11 and M12 are turned off. In this case, although the differential transistors M11 and M12 are turned off, a correction current is supplied to the differential amplifier 170A. Thereby, in a region 401 where the input signal 144 is in the low level, the output signal 145 indicates a false value.

Similarly, when the threshold voltage of the cut-off transistor MP46 is higher than the threshold voltage of the differential transistors MP11 and MP12 due to manufacturing variation, there are cases where the cut-off transistor MP46 is turned on in a state where the differential transistors MP11 and MP12 are turned off. In this case, although the differential transistors MP11 and MP12 are turned off, a correction current is supplied to the differential amplifier 170A. Thereby, in a region 402 where the input signal 144 is in the high level, the output signal 145 indicates a false value.

Embodiment 10 will describe an operational amplifier circuit 160K that can solve the problems.

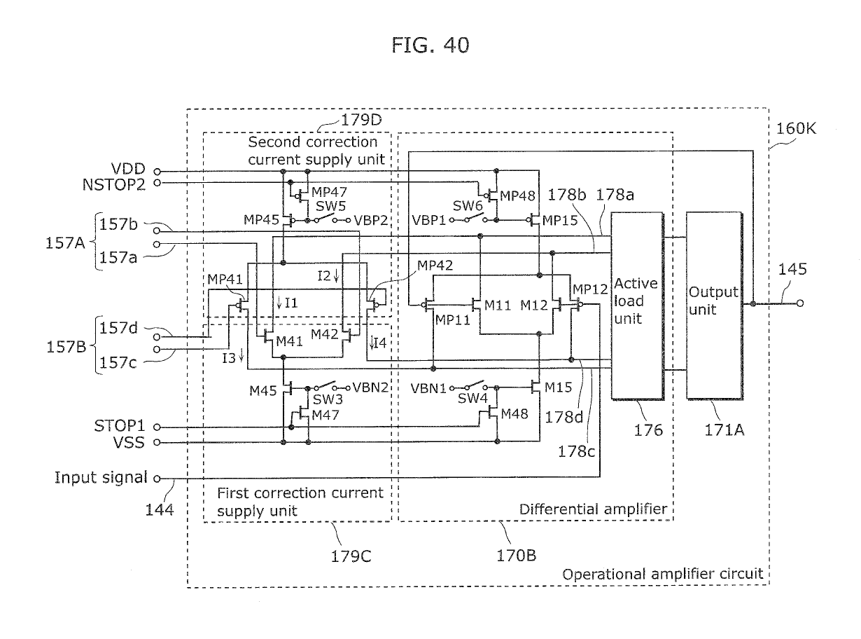

FIG. 40 illustrates a structure of the operational amplifier circuit 160K according to Embodiment 10. The same constituent elements as those in FIG. 16 are denoted by the same reference numerals, in FIG. 40.

The operational amplifier circuit 160K in FIG. 40 differs from the operational amplifier circuit 160B in FIG. 16 by the structure of the first correction current supply unit 179C, the second correction current supply unit 179D, and the differential amplifier 170B.

The first correction current supply unit 179C further includes a switch transistor M47 and a switch SW3 instead of the cut-off transistor M46, in addition to the constituent elements of the first correction current supply unit 179A.

Furthermore, the current source transistor M45 has a drain terminal connected to source terminals of correction transistors M41 and M42.

The switch transistor M47 has a gate terminal to which a first stop control signal STOP1 is applied, a drain terminal connected to a gate terminal of the current source transistor M45, and a source terminal connected to a ground potential line.

The switch SW3 is connected between the gate terminal of the current source transistor M45 and a voltage line to which a bias voltage VBN2 is applied. Furthermore, the switch SW3 is turned off when the first stop control signal STOP 1 is in the high level, and the switch SW3 is turned on when the first stop control signal STOP 1 is in the low level. Here, the switch SW3 is, for example, a transistor.

With the structure, when the first stop control signal STOP 1 is in the low level, the switch transistor M47 is turned off, and the switch

SW3 is turned on. Thereby, since the bias voltage VBN2 is applied to the gate terminal of the current source transistor M45, the first correction current supply unit 179C operates and correction currents I1 and 12 are supplied to the differential amplifier 170B.

On the other hand, when the first stop control signal STOP 1 is in the high level, the switch transistor M47 is turned on, and the switch SW3 is turned off. Thereby, since the ground potential VSS is applied to the gate terminal of the current source transistor M45, the current source transistor M45 is turned off. Thereby, the first correction current supply unit 179C stops supplying the correction currents I1 and I2 to the differential amplifier 170B.

The second correction current supply unit 179D further includes a switch transistor MP47 and a switch SW5 instead of the cut-off transistor M46, in addition to the constituent elements of the second correction current supply unit 179B.

Furthermore, the current source transistor M45 has a drain terminal connected to source terminals of correction transistors MP41 and MP42.

The switch transistor MP47 has a gate terminal to which a second stop control signal NSTOP2 is applied, a drain terminal connected to a gate terminal of the current source transistor MP45, and a source terminal connected to a power supply line.

The switch SW5 is connected between the gate terminal of the current source transistor MP45 and a voltage line to which a bias voltage VBP2 is applied. Furthermore, the switch SW5 is turned on when the second stop control signal NSTOP2 is in the high level, and the switch SW5 is turned off when the second stop control signal NSTOP2 is in the low level. Here, the switch SW5 is, for example, a transistor.

With the structure, when the second stop control signal NSTOP2 is in the high level, the switch transistor MP47 is turned off, and the switch SW5 is turned on. Thereby, since the bias voltage VBP2 is applied to the gate terminal of the current source transistor MP45, the second correction current supply unit 179D operates and correction currents I3 and I4 are supplied to the differential amplifier 170B.

When the second stop control signal NSTOP2 is in the low level, the switch MP47 is turned on, and the switch SW5 is turned off. Thereby, since the supply voltage VDD is applied to the gate terminal of the current source transistor MP45, the current source transistor MP45 is turned off. Thereby, the second correction current supply unit 179D stops supplying the correction currents I3 and I4 to the differential amplifier 170B.

The differential amplifier 170B further includes switch transistor M48 and MP48, and switches SW4 and SW6, in addition to the constituent elements of the differential amplifier 170A.

The switch transistor M48 has a gate terminal to which the first stop control signal STOP1 is applied, a drain terminal connected to a gate terminal of the current source transistor M15, and a source terminal connected to the ground potential line.

The switch SW4 is connected between the gate terminal of the current source transistor M15 and a voltage line to which a bias voltage VBN1 is applied. Furthermore, the switch SW4 is turned off when the first stop control signal STOP1 is in the high level, and is turned on when the first stop control signal STOP1 is in the low level. Here, the switch SW4 is, for example, a transistor.

With the structure, when the first stop control signal STOP1 is in the low level, the switch transistor M48 is turned off, and the switch SW4 is turned on. Thereby, since the bias voltage VBN1 is applied to the gate terminal of the current source transistor M15, an n-type differential pair of the differential transistors M11 and M12 operates.

On the other hand, when the first stop control signal STOP1 is in the high level, the switch transistor M48 is turned on, and the switch SW4 is turned off. Thereby, since the ground potential VSS is applied to the gate terminal of the current source transistor M15, the current source transistor M15 is turned off. Thereby, the n-type differential pair of the differential transistors M11 and M12 does not operate.

The switch transistor MP48 has a gate terminal to which the second stop control signal NSTOP2 is applied, a drain terminal connected to a gate terminal of the current source transistor MP15, and a source terminal connected to the power supply line.

The switch SW6 is connected between the gate terminal of the current source transistor MP15 and the voltage line to which a bias voltage VBP1 is applied. Furthermore, the switch SW6 is turned on when the second stop control signal NSTOP2 is in the high level, and is turned off when the second stop control signal NSTOP2 is in the low level. Here, the switch SW6 is, for example, a transistor.

With the structure, when the second stop control signal NSTOP2 is in the high level, the switch transistor MP48 is turned off, and the switch SW6 is turned on. Thereby, since the bias voltage VBP1 is applied to the gate terminal of the current source transistor MP15, a p-type differential pair of the differential transistors MP11 and MP12 operates.

When the second stop control signal NSTOP2 is in the low level, the switch MP48 is turned on, and the switch SW6 is turned off. Thereby, since the supply voltage VDD is applied to the gate terminal of the current source transistor MP15, the current source transistor MP15 is turned off. Thereby, the p-type differential pair of the differential transistors MP11 and MP12 does not operate.

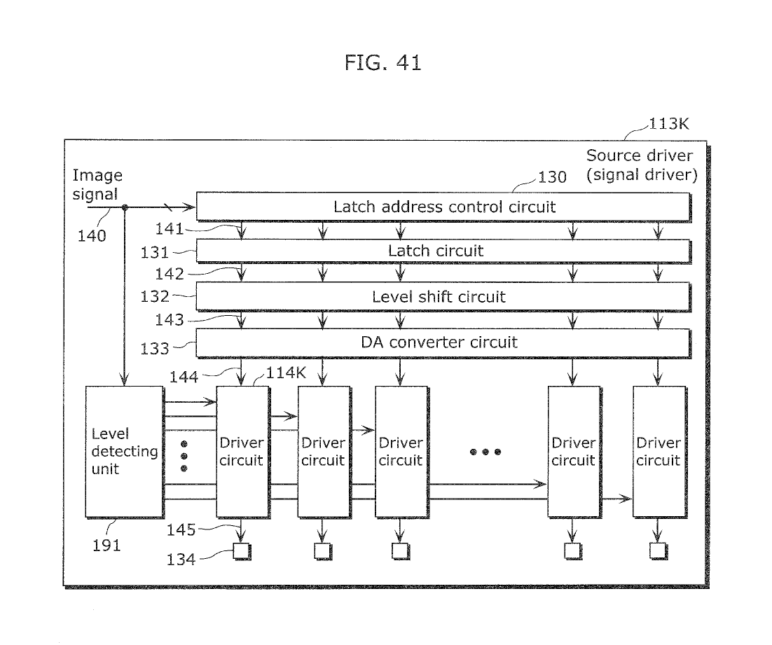

FIG. 41 is a block diagram illustrating a structure of a source driver 113K according to Embodiment 10.

The source driver 113K in FIG. 41 further includes a level detecting unit 191, in addition to the constituent elements of the source driver 113 in FIG. 3. Furthermore, the source driver 113K includes driver circuits 114K instead of the driver circuits 114. Each of the driver circuits 114K includes the operational amplifier circuit 160K in FIG. 40.

The level detecting unit 191 generates the first stop control signal STOP1 and the second stop control signal NSTOP2 corresponding to each of the driver circuits 114K, based on an image signal 140. The level detecting unit 191 detects a signal level indicated by the image signal 140, and controls each of (i) the n-type differential pair and the p-type differential pair included in the differential amplifier 170B, (ii) the first correction current supply unit 179C, and (iii) the second correction current supply unit 179D to operate or stop operating, according to the detected signal level.

More specifically, the level detecting unit 191 stops supplying a correction current from the second correction current supply unit 179D to the p-type differential pair when the voltage of the input signal 144 is equal to or higher than the first threshold. Furthermore, the level detecting unit 191 stops supplying a correction current from the first correction current supply unit 179C to the n-type differential pair when the voltage of the input signal 144 is equal to or lower than the second threshold that is lower than the first threshold. Furthermore, the level detecting unit 191 determines whether the voltage of each of the input signals 144 is equal to or higher than the first threshold or equal to or lower than the second threshold, based on the image signal 140 that is a digital signal.

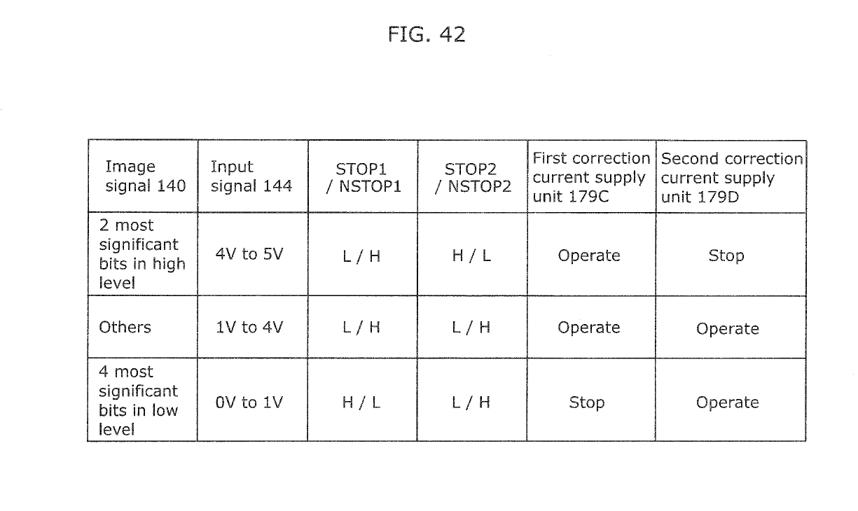

FIG. 42 illustrates an example of operations performed by the level detecting unit 191. Here, the example in FIG. 42 indicates a case where the supply voltage VDD is 5 V.

As illustrated in FIG. 42, the level detecting unit 191 determines whether 2 most significant bits of the image signal 140 that is a digital signal are in the high level, all the 4 most significant bits of the image signal 140 are in the low level, or the image signal 140 is in other states.

When the 2 most significant bits of the image signal 140 are in the high level, the level detecting unit 191 determines that the input signal 144 is equal to or higher than 4 V (the first threshold), and sets the first stop control signal STOP1 and the second stop control signal NSTOP2 to the low level. Thereby, the first correction current supply unit 179C operates, and the second correction current supply unit 179D stops operating. Furthermore, the n-type differential pair included in the differential amplifier 170B operates, and the p-type differential pair included therein stops operating.

Furthermore, when all the 4 most significant bits of the image signal 140 are in the low level, the level detecting unit 191 determines that the input signal 144 is equal to or lower than 1 V (the second threshold), and sets the first stop control signal STOP1 and the second stop control signal NSTOP2 to the high level. Thereby, the first correction current supply unit 179C stops operating, and the second correction current supply unit 179D operates. Furthermore, the n-type differential pair included in the differential amplifier 170B stops operating, and the p-type differential pair included therein operates.

Furthermore, when the image signal 140 are in other states, the level detecting unit 191 determines that the input signal 144 is in a range of 1 V to 4 V (higher than the second threshold and lower than the first threshold), and sets the first stop control signal STOP1 to the low level and the second stop control signal NSTOP2 to the high level. Thereby, both the first correction current supply unit 179C and the second correction current supply unit 179D operate. Furthermore, both the n-type differential pair and the p-type differential pair included in the differential amplifier 170B operate.

Here, the second threshold (1 V in the aforementioned example) of the input signal 144 used by the level detecting unit 191 to stop operating the first correction current supply unit 179C and the n-type differential pair has only to be equal to or larger than a value obtained by adding a predetermined margin to the threshold voltage of an n-type MOS transistor. For example, assuming that the threshold voltage of the n-type MOS transistor is 0.8 V, it is preferred that the second threshold should be approximately in a range of 1.0 V to 1.5 V that is determined by adding a predetermined margin (0.2 V, example) to 0.8 V.

Furthermore, the first threshold (4 V in the aforementioned example) of the input signal 144 used by the level detecting unit 191 to stop operating the second correction current supply unit 179D and the p-type differential pair has only to be equal to or smaller than a value obtained by subtracting, from a supply voltage, a value obtained by adding a predetermined margin to the threshold voltage of a p-type MOS transistor. For example, it is preferred that the first threshold should be approximately a value in a range of 3.5 V to 4.0 V that is determined by subtracting approximately 1.0 V to 1.5 V from a supply voltage (5 V).

Furthermore, the level detecting unit 191 may make the determination using a parallel data item 141, a latched data item 142, or a conversion data item 143 that is a digital signal, instead of the image signal 140.

As described above, the operational amplifier circuit 160K according to Embodiment 10 stops operating the first correction current supply unit 179C and the n-type differential pair when the input signal 144 is equal to or smaller than a predetermined second threshold (1 V in the aforementioned example). Thereby, it is possible to prevent a correction current from being supplied to the n-type differential pair after the n-type differential pair stops operating due to variation in threshold voltage of a transistor. Thus, the operational amplifier circuit 160K can prevent the output signal 145 from indicating a false value in the region 401 where the input signal 144 is lower.

Furthermore, the operational amplifier circuit 160K according to Embodiment 10 stops operating the second correction current supply unit 179D and the p-type differential pair when the input signal 144 is equal to or smaller than a predetermined first threshold (4 V in the aforementioned example). Thereby, it is possible to prevent a correction current from being supplied to the p-type differential pair after the p-type differential pair stops operating due to variation in threshold voltage of a transistor. Thus, the operational amplifier circuit 160K can prevent the output signal 145 from indicating a false value in the region 402 where the input signal 144 is higher.

Thereby, the operational amplifier circuit 160K according to Embodiment 10 can correct an input offset voltage in an entire voltage range within which the input signal 144 can fall.

Although the operational amplifier circuit 160K stops operating the first correction current supply unit 179C and the n-type differential pair when the input signal 144 is equal to or smaller than the second threshold (1 V in the aforementioned example), it may stop operating only the first correction current supply unit 179C. Even in this case, it is possible to prevent a correction current from being supplied to the n-type differential pair after the n-type differential pair stops operating due to variation in threshold voltage of a transistor. However, the presence of offset in the n-type differential pair indicates that the input signal 144 is equal to or smaller than the second threshold, and the influence of the offset appears in a region where the n-type differential pair operates. Thus, when the input signal 144 is equal to or smaller than the second threshold (1 V in the aforementioned example) as in the structure in FIG. 40, preferably, the operational amplifier circuit 160K stops operating both the first correction current supply unit 179C and the n-type differential pair.

Similarly, the operational amplifier circuit 160K may stop operating only the second correction current supply unit 179D when the input signal 144 is equal to or larger than the first threshold (4 V in the aforementioned example).

Furthermore, the operational amplifier circuit 160K may use the following structure.

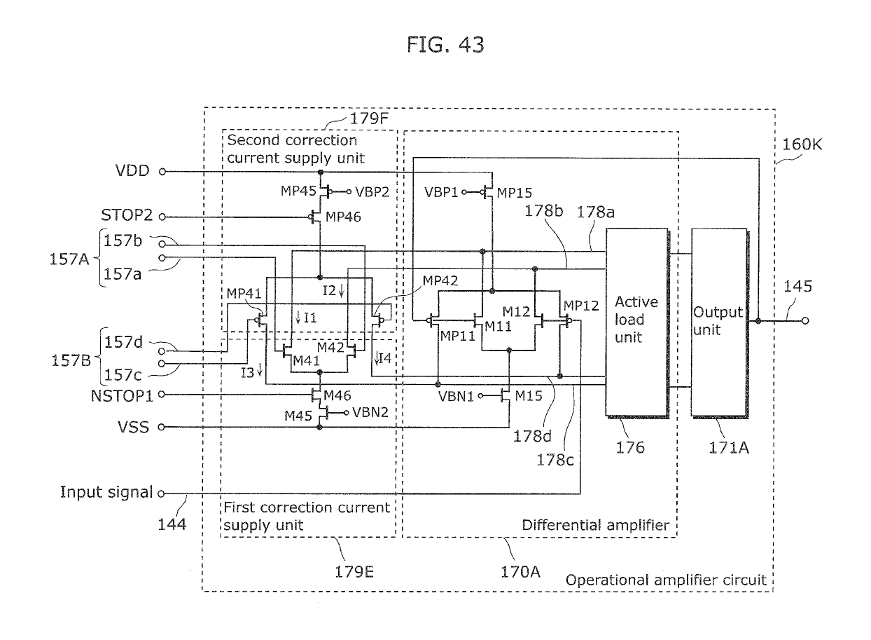

FIG. 43 illustrates a structure of a modified example of the operational amplifier circuit 160K.

The operational amplifier circuit 160K in FIG. 43 differs from the operational amplifier circuit 160B in FIG. 16 by the structure of a first correction current supply unit 179E and a second correction current supply unit 179F.

More specifically, the difference is that a first stop control signal NSTOP1 is supplied to a gate terminal of a cut-off transistor M46 included in the first correction current supply unit 179E, and a second stop control signal STOP2 is supplied to a gate terminal of a cut-off transistor MP46 included in the second correction current supply unit 179F.

Here, the first stop control signal NSTOP1 is an inversion signal of the first stop control signal STOP1, and the second stop control signal STOP2 is an inversion signal of the second stop control signal NSTOP2.

The structure in FIG. 43 can implement the functions as the structure in FIG. 40.

Although the structure in FIG. 43 is for stopping operations of only one of the first correction current supply unit 179E and the second correction current supply unit 179F, the structure may be for stopping operations of the n-type differential pair and the p-type differential pair as in FIG. 40.

As described in Embodiment 8, the operational amplifier circuit 160K may control one of the first correction current supply unit 179E and the second correction current supply unit 179F to stop supplying the correction current to the differential amplifier 170B during a predetermined period immediately after the input signal 144 is changed.

More specifically, the level detecting unit 191 has only to have the aforementioned functions. In other words, the level detecting unit 191 prevents (i) the first correction current supply unit 179C from supplying a correction current to the n-type differential pair, and (ii) the second correction current supply unit 179D from supplying a correction current to the p-type differential pair, for a predetermined period from the time when the input signal 144 is changed (the period T1 in FIG. 35). Thereby, the operational amplifier circuit 160K can shorten the time until when the output signal 145 reaches a predetermined voltage.

Furthermore, in this case, a circuit for stopping supplying a correction current equal to or higher than the first threshold (or equal to or smaller than the second threshold) and a part of a circuit for stopping supplying a correction current when the input signal 144 is changed may be shared.

Furthermore, each of the processing units included in the display devices according to Embodiments 1 to 10, is typically achieved in the form of an integrated circuit or a Large Scale Integrated (LSI) circuit. Furthermore, each of the processing units may be made into one chip individually, or a part or an entire thereof may be made into one chip.

The name used here is LSI, but it may also be called IC, system LSI, super LSI, or ultra LSI depending on the degree of integration.

Moreover, ways to achieve integration are not limited to the LSI, and a special circuit or a general purpose processor and so forth can also achieve the integration. It is also acceptable to use a Field Programmable Gate Array (FPGA) that is programmable after the LSI has been manufactured, and a reconfigurable processor in which connections and settings of circuit cells within the LSI are reconfigurable.

In the future, with advancement in semiconductor technology, a brand-new technology may replace LSI. Each of the processing units can be integrated using such a technology.

A part or an entire of the functions of the display devices according to Embodiments 1 to 7 can be implemented by causing a processor, such as a CPU to execute a program.

Furthermore, the present invention may be the program, or a recording medium on which the program is recorded. Furthermore, such a program may be distributed via a transmission medium, such as the Internet.

At least parts of the functions of the operational amplifier circuits, signal processors (the source drivers), the display devices according to Embodiments 1 to 7 and the modified examples thereof may be combined.

Since the values used in Embodiments are all exemplifications for specifically describing the present invention, the present invention is not limited to the exemplified values. Furthermore, since the logic level represented by high or low or a switching state represented by ON or OFF are exemplifications for specifically describing the present invention, a different combination of the exemplified logic levels or the switching states may result in the equivalent result. Furthermore, since the n-type and p-type of a transistor or others are exemplifications for specifically describing the present invention, inversion of these types may result in the equivalent result. Furthermore, since the connection relationships between the constituent elements are exemplifications for specifically describing the present invention, the connection relationships for implementing the functions of the present invention are not limited to these in the description.

Although the MOS transistors are used as the examples in Embodiments, other transistors, such as bipolar transistors, may be used.

More specifically, when bipolar transistors are used, the n-type MOS transistor has only to be replaced with an N-P-N bipolar transistor, and the p-type MOS transistor has only to be replaced with a P-N-P bipolar transistor. Furthermore, the gate terminal has only to be replaced with a base terminal, the source terminal has only to be replaced with an emitter terminal, and the drain terminal has only to be replaced with a collector terminal.

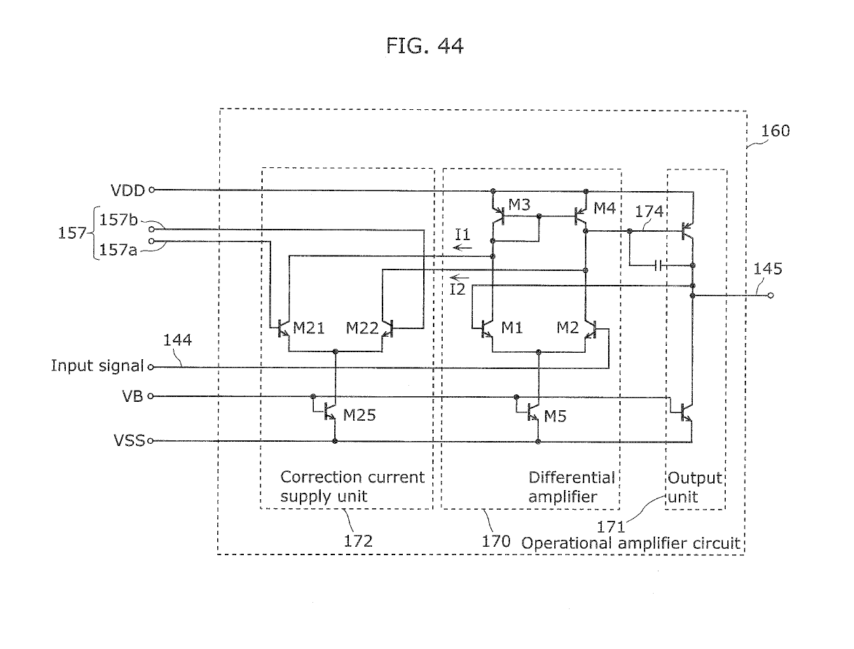

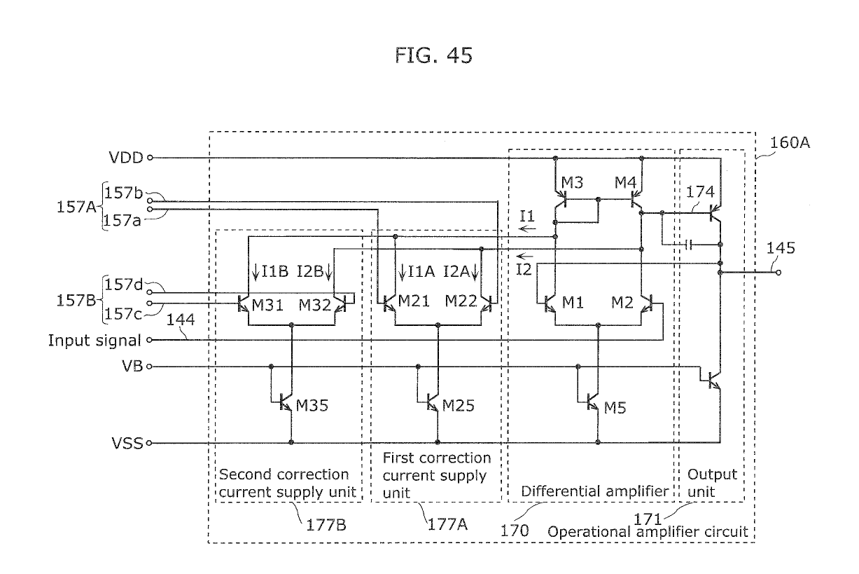

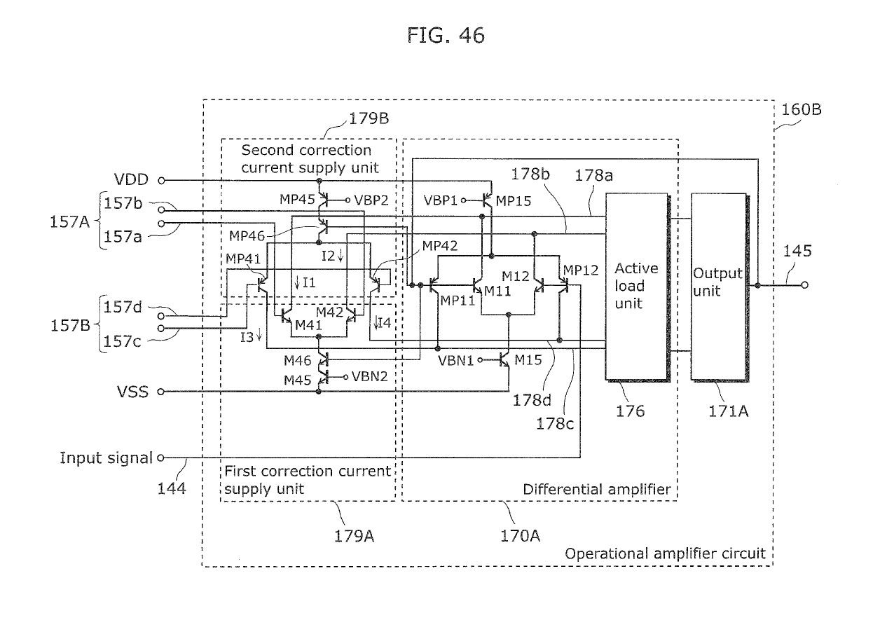

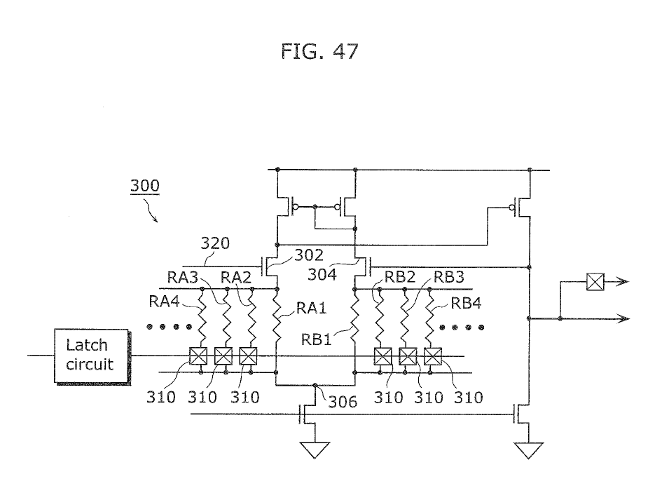

FIGS. 44, 45, and 46 illustrate circuits in which bipolar transistors are used in the circuits in FIGS. 7, 13, and 16, respectively.

Furthermore, since the order in which each of the signal processors performs the steps included in the processes of adjusting an input offset voltage is an exemplification for specifically describing the present invention, the order may be any. Furthermore, a part of the steps may be performed simultaneously (in parallel) with other steps.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention is applicable to operational amplifier circuits, signal processors, and display devices, and in particular to liquid crystal displays and EL displays.

What is claimed is:

1. A signal driver that drives input signals and outputs output signals corresponding to the driven input signals, said signal driver comprising
operational amplifier circuits each provided to a correspond one of the input signals and each including a first input terminal, a second input terminal, and an output terminal, each of said operational amplifier circuits having (i) a non-inverting input terminal that receives a corresponding one of the input signals and (ii) an inverting input terminal connected to said output terminal, and outputting, to said output terminal, a corresponding one of the output signals, the non-inverting input terminal being one of said first input terminal and said second input terminal, and the inverting input terminal being the other of said first input terminal and said second input terminal;
a voltage generating unit configured to generate voltage signals having different voltage values; and
selecting units each provided to a corresponding one of said operational amplifier circuits, and configured to select one of the voltage signals, and to output the selected voltage signal as a first correction voltage signal to a corresponding one of said operational amplifier circuits,
each of said operational amplifier circuits further including:
a differential amplifier that amplifies a potential difference between said first input terminal and said second input terminal, and outputs, to said output terminal, the amplified difference as an output signal; and
a first correction current supply unit configured to supply said differential amplifier with a first correction current corresponding to the first correction voltage signal to adjust an input offset voltage of said operational amplifier circuit, and
said differential amplifier including:
a first differential transistor having a gate terminal connected to said first input terminal;
a second differential transistor having a gate terminal connected to said second input terminal, and forming a first differential pair with said first differential transistor; and
a first current source transistor that supplies a current to source terminals of said first differential transistor and said second differential transistor,
wherein said first correction current supply unit is configured to supply the first correction current to a drain terminal of said first differential transistor.

2. The signal driver according to claim 1,
wherein said signal driver has a normal operation mode for driving each of the input signals, and an adjustment mode for adjusting the input offset voltage of each of said operational amplifier circuits,
said signal driver further comprises storage units each provided to a corresponding one of said operational amplifier circuits, and in each of which setting information for specifying one of the voltage signals is stored,
each of said selecting units is configured to select, in the normal operation mode, the one of the voltage signals specified by the setting information stored in a corresponding one of said storage units,
said signal driver further comprises:
a control unit configured to control, in the adjustment mode, each of said selecting units to sequentially select one of the voltage signals; and
a comparing and determining unit configured to compare the output signals with the input signals, and
in the adjustment mode, said control unit is configured to:
determine, for each of said operational amplifier circuits, one of the voltage signals so that the input offset voltage of a corresponding one of said operational amplifier circuits is in a predetermined range, using a result of comparison for each of the voltage signals selected by said selecting units, the comparison being performed by said comparing and determining unit; and
store the setting information specifying the determined voltage signal in one of said storage units corresponding to said operational amplifier circuit.

3. The signal driver according to claim 1, further comprising:
a latch address control circuit that converts, into parallel data items, serial data received from outside of said signal driver;
a latch circuit that latches the parallel data items as latched data items;
a level shift circuit that converts voltage levels of the latched data items to generate conversion data items; and
a digital-analog (DA) converter circuit that converts the conversion data items into the input signals that are analog signals.

4. A display device including said signal driver according to claim 2, said display device comprising:
a display unit configured to display images corresponding to the output signals output from said signal driver; and
a mode control unit configured to set said signal driver to the adjustment mode during a non-display period in which said display unit does not display the images.

5. A display device including said signal driver according to claim 1, said display device comprising
a display unit configured to display images corresponding to the output signals output from said signal driver,
wherein said display unit includes liquid crystal cells or organic electroluminescence (EL) cells that emit light according to the output signals.
